(19) United States
(12) Patent Application Publication
(10) Pub. No.: US 2025/0203994 A1
(43) Pub. Date: Jun. 19, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Jyun-Guan JHOU, Hsinchu City (TW); Po-Chih SU, Hsinchu City (TW); Pei-Lun WANG, Zhubei City (TW); Wan-Jyun SYUE, Hsinchu County (TW); Victor Chiang LIANG, Hsinchu City (TW); Yu-Chang JONG, Hsinchu City (TW)

(21) Appl. No.: 18/404,359

(22) Filed: Jan. 4, 2024

Related U.S. Application Data
(60) Provisional application No. 63/611,993, filed on Dec. 19, 2023.

(51) Int. Cl. H01L 29/40; H01L 29/66; H01L 29/78

(52) U.S. Cl. CPC H10D 64/111; H10D 30/0281; H10D 30/65; H10D 64/01

(57) ABSTRACT

A transistor structure includes a field plate structure and a plurality of dielectric structures through the field plate structure. The dielectric structures may be arranged in a grid in a top view of the transistor structure. The dielectric structures enable the field plate structure to be positioned closer to a gate structure of the transistor than without the dielectric structures, which enables the length of the field plate structure to be increased without increasing the overall length (or with minimal length increase) of the transistor.

### CROSS-REFERENCE TO RELATED APPLICATION

This patent application claims priority to U.S. Provisional Patent Application No. 63/611,993, filed on Dec. 19, 2023, and entitled “SEMICONDUCTOR DEVICE AND METHODS OF FORMATION.” The disclosure of the prior application is considered part of and is incorporated by reference into this patent application.

### BACKGROUND

A high-voltage transistor is a type of metal oxide semiconductor (MOS) transistor that may be configured to operate at a higher drain voltage relative to a low voltage transistor. Low voltage transistors may be used in applications such as logic circuits (e.g., processors), memory (e.g., static random access memory (SRAM), and/or input/output (I/O) circuits, among other examples. High-voltage transistors may be used in applications such as integrated circuit (IC) drivers, power ICs, image sensors, power management, display driver ICs (DDICs), bipolar complementary metal oxide semiconductor (CMOS) diffused metal oxide semiconductor (DMOS) ICs (BCD ICs), and/or image signal processing (ISP) ICs, among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of a portion of an example semiconductor device described herein.

FIGS. 3A-3C are diagrams of an example transistor structure described herein.

FIG. 4 is a diagram of an example implementation of a transistor structure described herein.

FIGS. 5A-5Q are diagrams of an example implementation of forming a transistor structure described herein.

FIGS. 6A-6C are diagrams of example implementations of a transistor structure described herein.

FIG. 7 is a diagram of example components of a device described herein.

FIG. 8 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a transistor (e.g., a high-voltage transistor) includes a field plate layer. A field plate layer is a conductive layer that is included over a portion of a channel region of the transistor between a gate structure and a drain region of the transistor. The field plate layer may increase the performance of the transistor by enabling the field plate layer to be used to manipulate an electric field (e.g., reducing the peak of the electric field) that is generated using a gate structure of the transistor. By manipulating the electric field generated by the gate structure, the transistor can achieve a greater breakdown voltage with less on-state resistance (R_{dson}) at greater operating voltages than without the field plate layer.

The length of the field plate layer may be selected based on the operating voltage of the transistor to satisfy a breakdown voltage parameter for the transistor. For example, the length of the field plate layer may be increased to enable the transistor to achieve a sufficiently high breakdown voltage for the transistor. While this enables the transistor to operate at a high operating voltage, increasing the length of the field plate layer increases the distance between the gate structure and the drain region. The increased distance between the gate structure and the drain region increases the device pitch of the transistor, which reduces the transistor device density that can be achieved on a semiconductor device. The increased device pitch of the transistor may reduce the operating efficiency of the transistor, may increase resistance (e.g., may increase R_{dson}) in the transistor, and/or may result in reduced density of transistors in a semiconductor device, among other examples.

In some implementations described herein, a transistor structure (e.g., a high-voltage transistor) includes a field plate structure and at least one dielectric structure through the field plate structure. The dielectric structure(s) may be arranged in a grid in a top view of the transistor structure. The dielectric structure(s) enable the field plate structure to be positioned closer to a gate structure of the transistor than without the dielectric structure(s), which enables the length of the field plate structure to be increased without increasing the overall length (or with minimal length increase) of the transistor.

The gate structure, the field plate structure, and openings through the field plate structure for the dielectric structure(s) are all formed by etching a layer of gate material. The remaining portions of the layer of gate material correspond to the gate structure and field plate structure. The openings are then filled with a dielectric material to form the dielectric structure(s) in the field plate structure. Without the dielectric structure(s), a pattern in a photoresist that would be used to etch the layer of gate material would otherwise be considered an isolated space, meaning that the pattern would otherwise have a very low feature density. As a result, the majority of the area of the transistor would otherwise be blocked from exposure during a photolithography operation, resulting in low exposure efficiency and/or an increased likelihood of underdevelopment of the pattern. The increased likelihood of underdevelopment of the pattern may result in residual photoresist material (referred to as photoresist scum), which may cause defects to occur in etching the layer of gate material. In particular, the residual photoresist material may result in under etching between the gate structure and the field plate structure, which may result in bridging (and electrical shorting) between the gate structure and the field plate structure. Spacing the gate structure and field plate structure further apart might increase the exposure efficiency in that a greater amount of luminous flux might reach the photoresist between where the gate structure and the field plate structure are to be formed. However, this would otherwise increase the device pitch of the transistor, resulting in the increased resistance and/or reduced density described above.

By including the dielectric structure(s) in the field plate structure described herein, the feature density in the pattern that is used to form the gate structure, the field plate structure, and the recesses through the field plate structure is increased such that the pattern is a densely populated pattern. The densely populated pattern enables a greater amount of luminous flux to be exposed to the underlying photoresist in which the pattern is formed. The greater amount of luminous flux enables the gate structure and the field plate structure to be spaced closer together while still permitting a sufficient amount of luminous flux to reach the photoresist to ensure full development of the pattern.

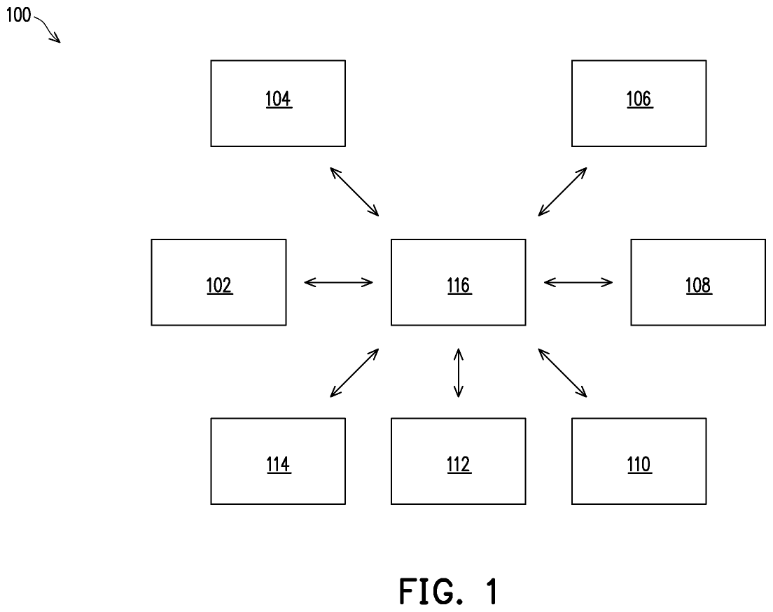

FIG. 1 is a diagram of an example environment 100 in which systems and/or methods described herein may be implemented. As shown in FIG. 1, the example environment 100 may include a plurality of semiconductor processing tools 102-114 and a wafer/die transport tool 116. The plurality of semiconductor processing tools 102-114 may include a deposition tool 102, an exposure tool 104, a developer tool 106, an etch tool 108, a planarization tool 110, a plating tool 112, an ion implantation tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The ion implantation tool 114 is a semiconductor processing tool that is used to implant ions into a substrate such as a semiconductor wafer. The ion implantation tool 114 generates ions in an arc chamber from a source material such as a gas or a solid. The source material is provided into the arc chamber, and an arc voltage is discharged between a cathode and an electrode to produce a plasma containing ions of the source material. One or more extraction electrodes are used to extract the ions from the plasma in the arc chamber and accelerate the ions to form an ion beam. The ion beam may be directed toward the substrate such that the ions are implanted below the surface of the substrate to dope the substrate.

Wafer/die transport tool 116 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-114, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 116 may be a programmed device that is configured to travel a particular path and/or may operate semi-autonomously or autonomously. In some implementations, the example environment 100 includes a plurality of wafer/die transport tools 116.

For example, the wafer/die transport tool 116 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 116 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

In some implementations, one or more of the semiconductor processing tools 102-114 and/or the wafer/die transport tool 116 may be used to perform one or more semiconductor processing operations described herein. For example, one or more of the semiconductor processing tools 102-114 and/or the wafer/die transport tool 116 may be used to form a layer of gate material over a substrate of a semiconductor device; may be used to form a patterned photoresist layer over the layer of gate material; may be used to etch, using the patterned photoresist layer, the layer of gate material to form a gate structure of a transistor structure included in the semiconductor device, a field plate structure, of the transistor structure, adjacent to a first side of the gate structure, and at least one opening through the field plate structure; may be used to form a at least one dielectric structure in the at least one opening through the field plate structure; may be used to form a first source/drain region, of the transistor structure, in the substrate, where the first source/drain region is adjacent to a second side of the gate structure opposing the first side; and/or may be used to form a second source/drain region, of the transistor structure, in the substrate, where the second source/drain region is adjacent to the field plate structure, among other examples.

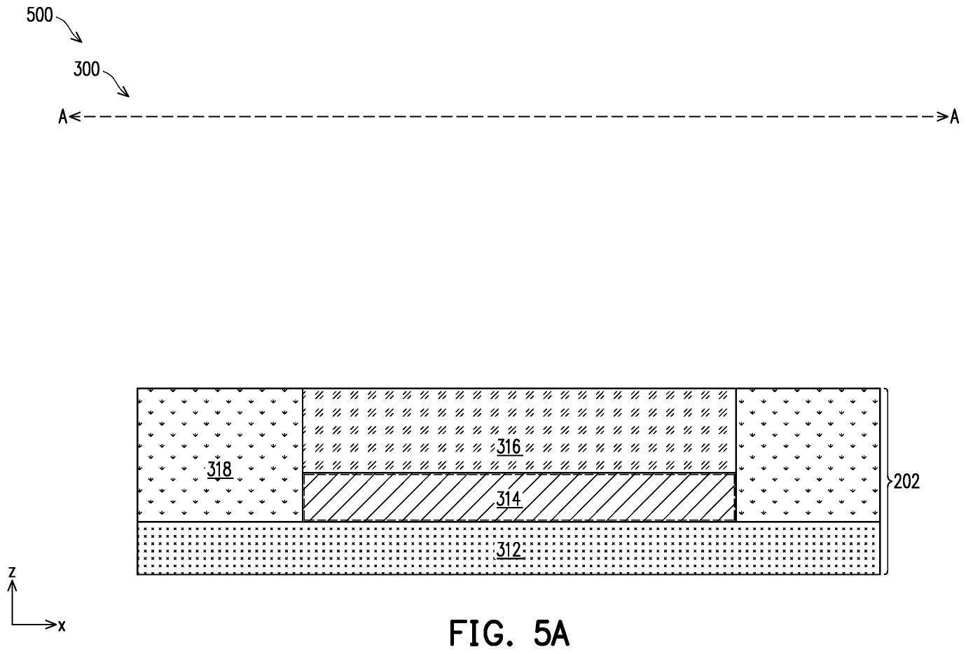

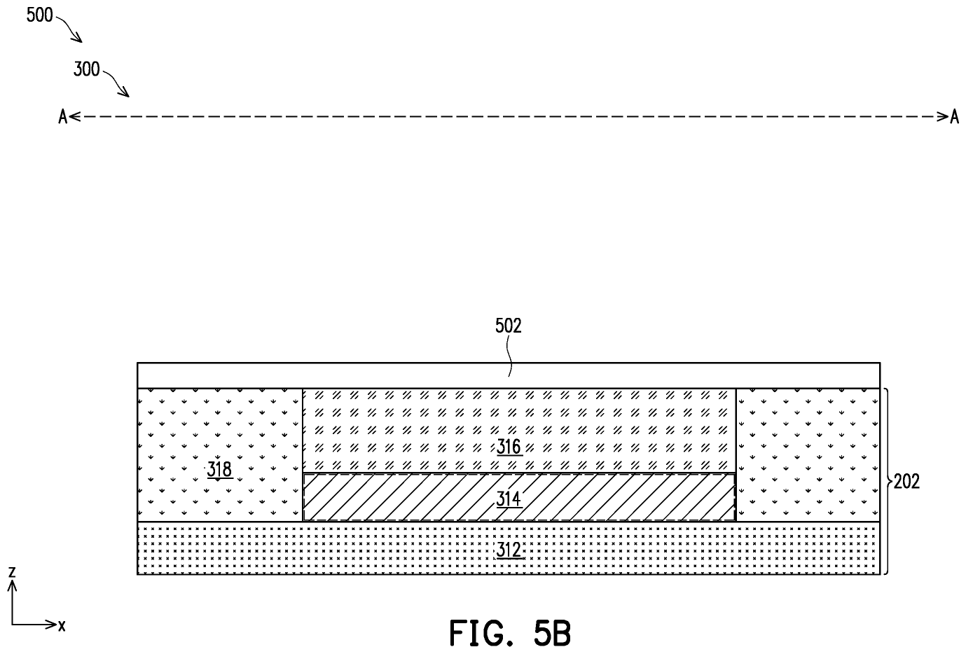

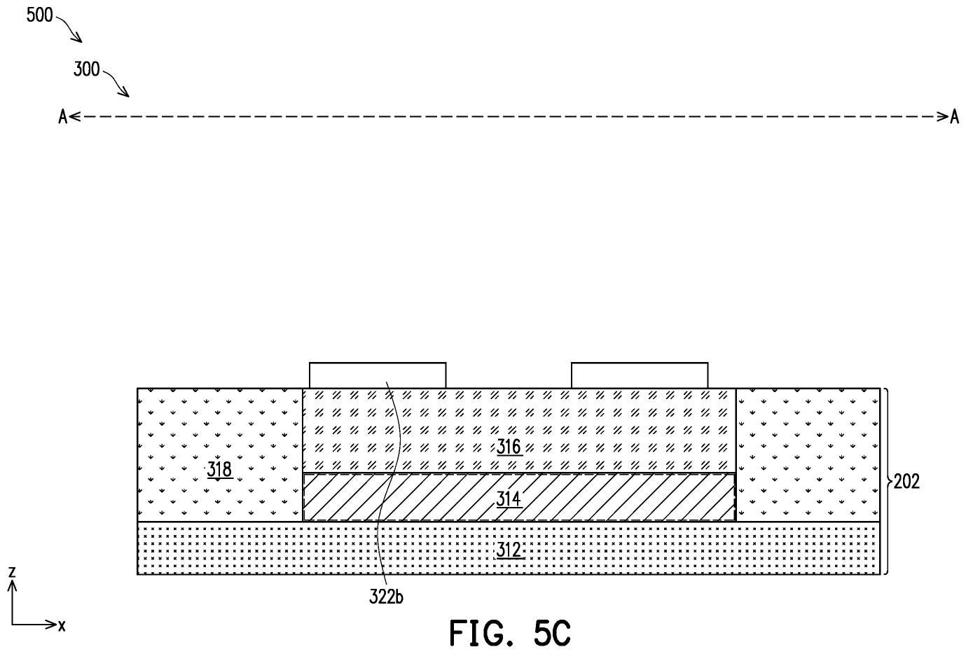

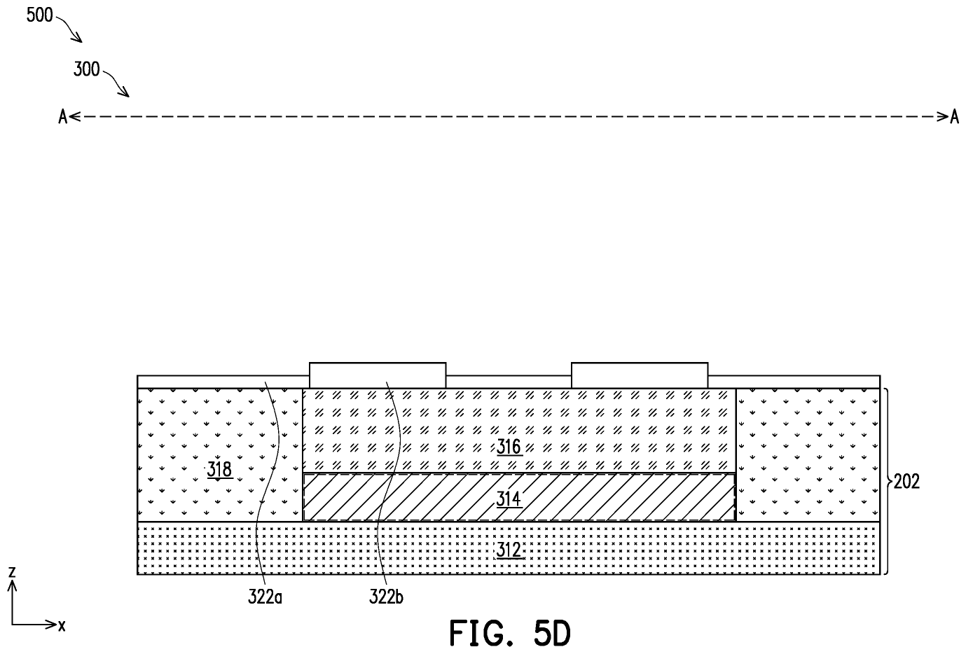

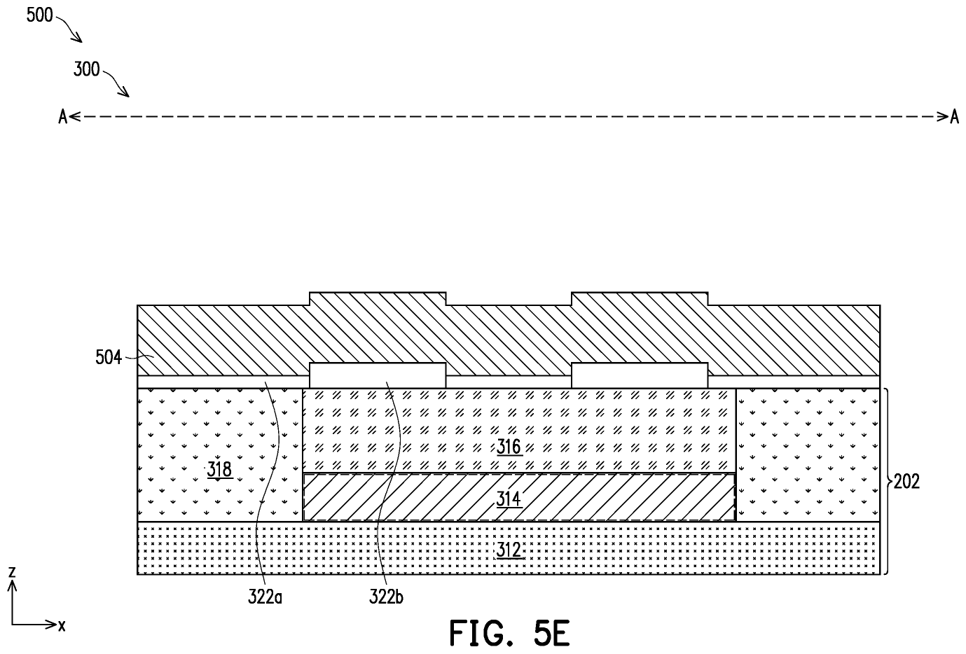

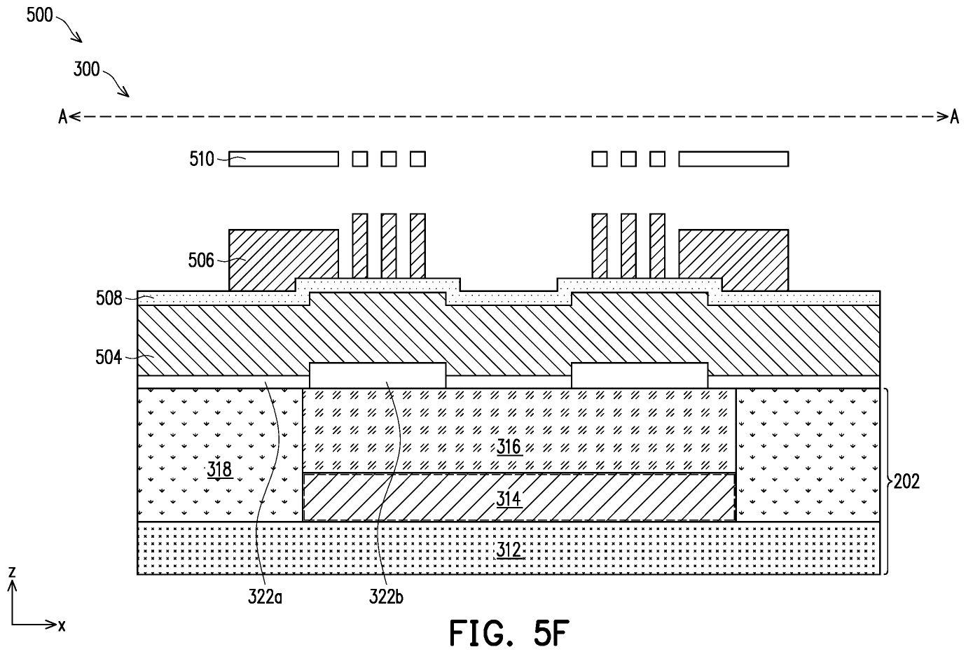

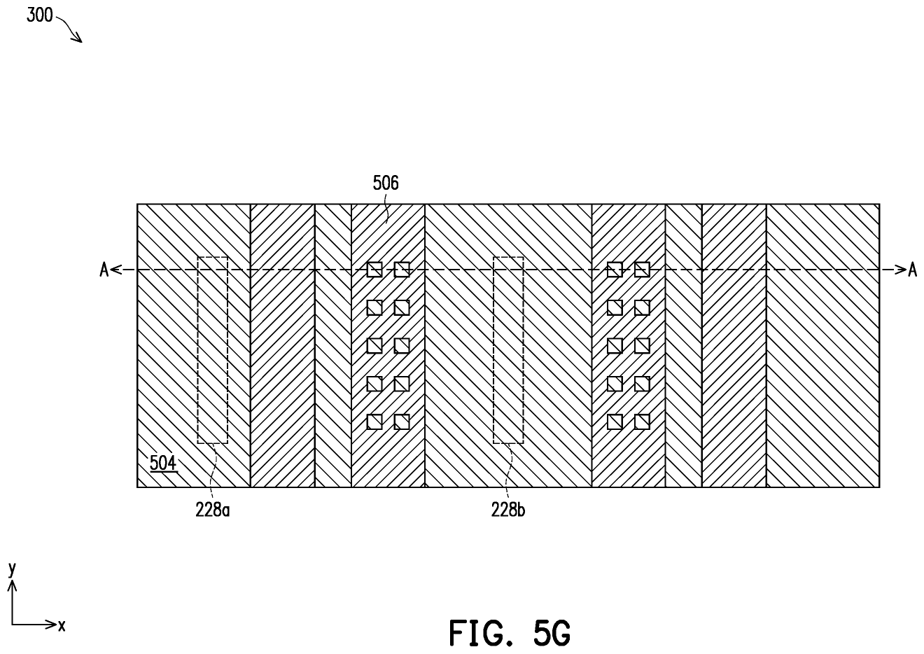

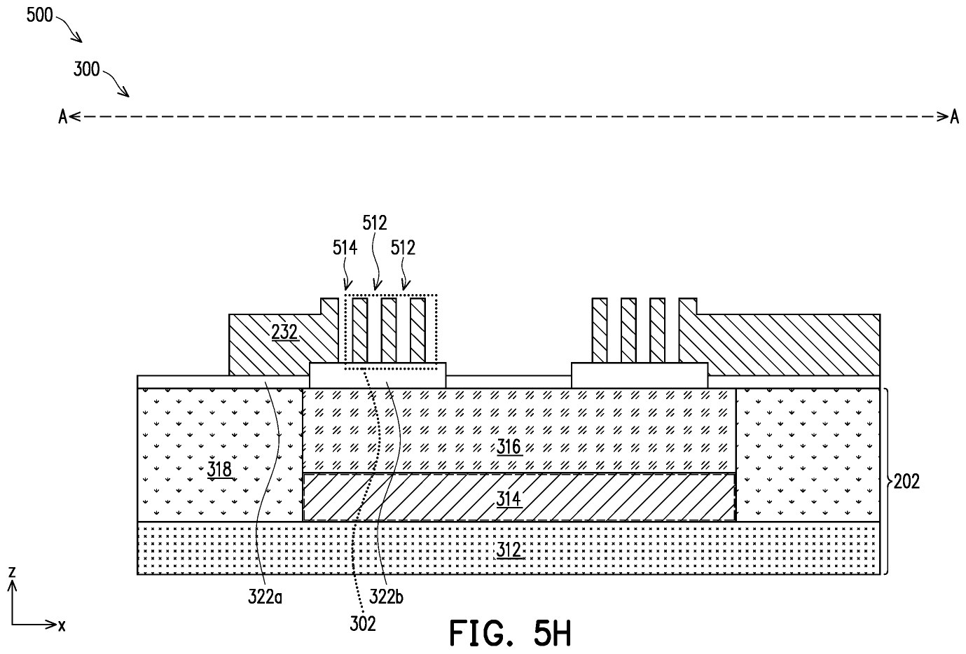

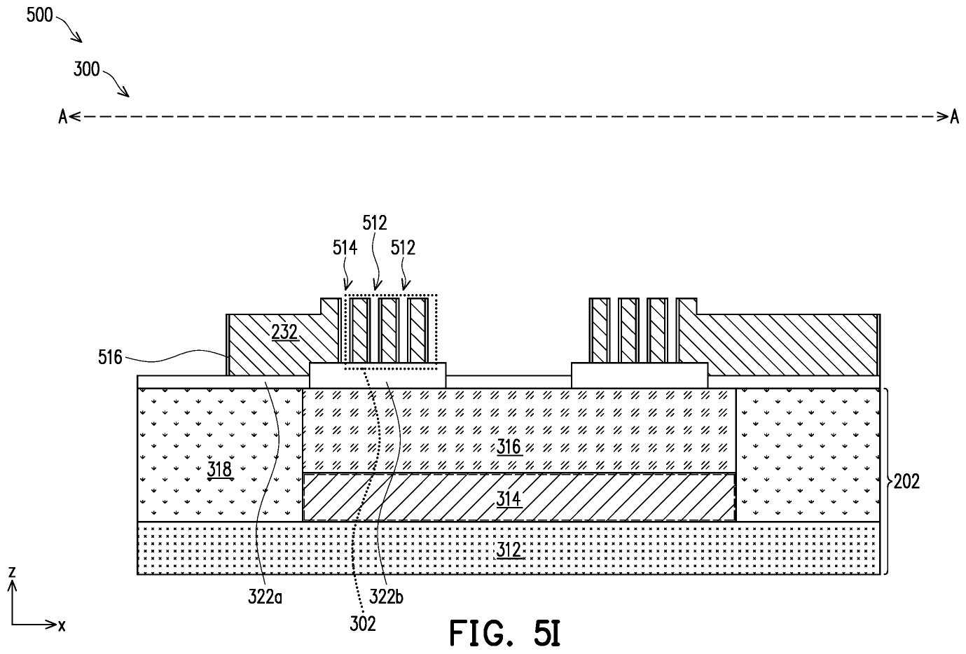

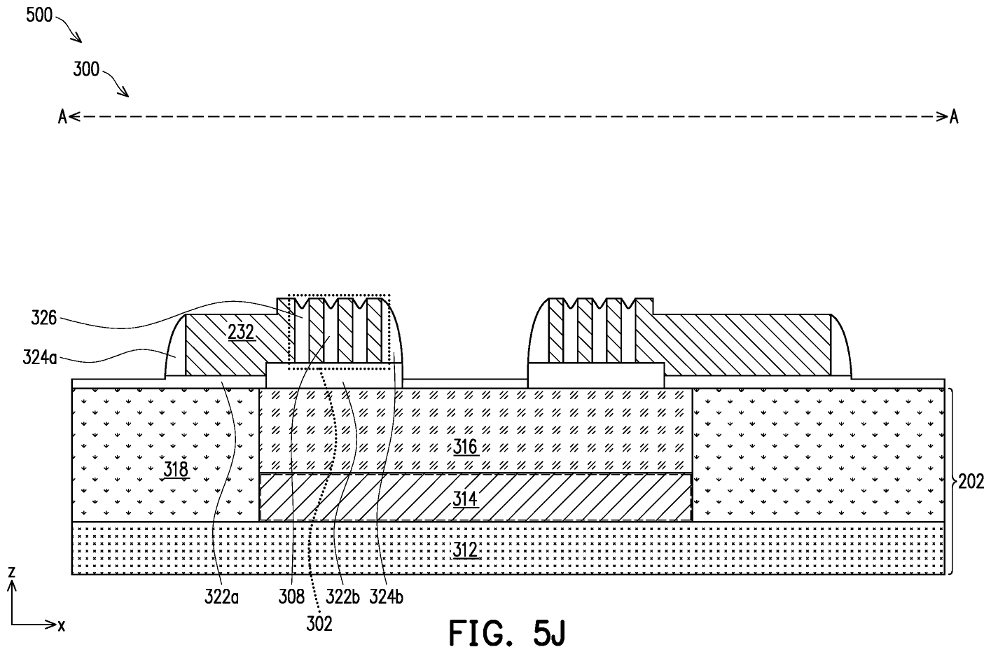

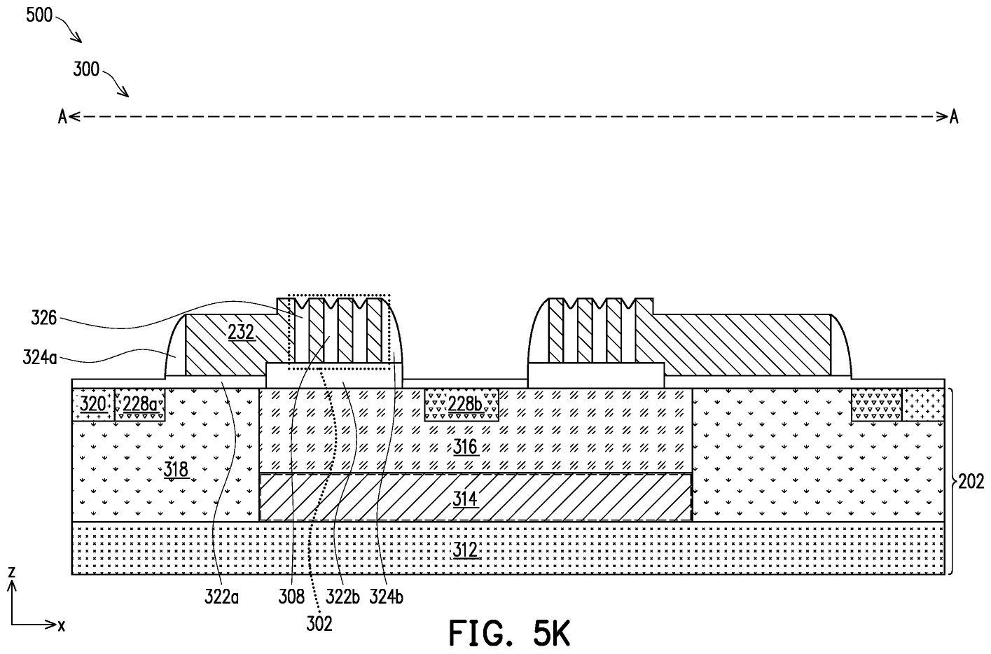

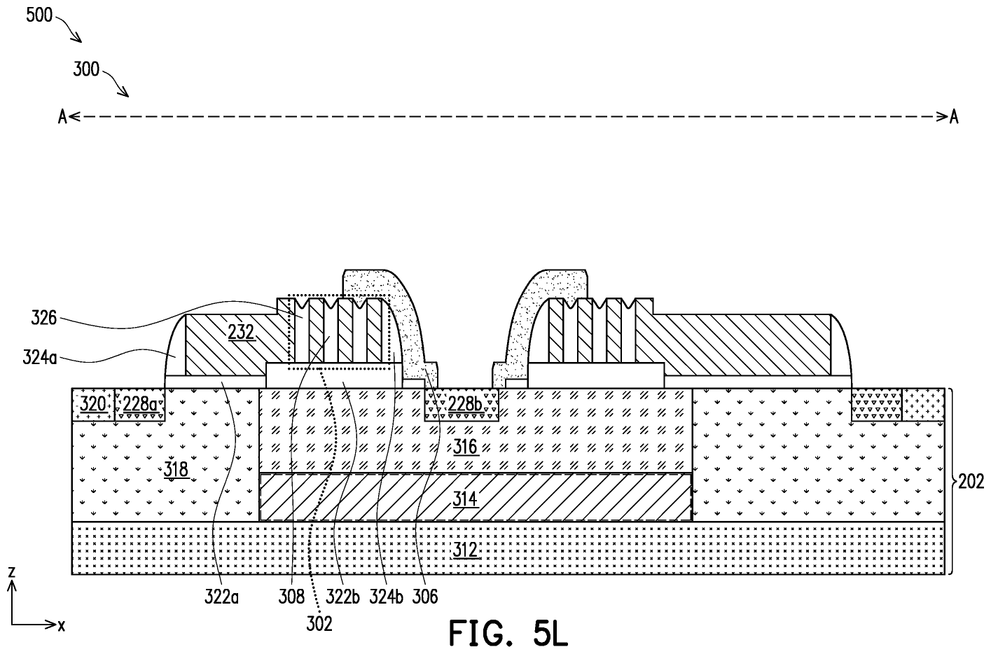

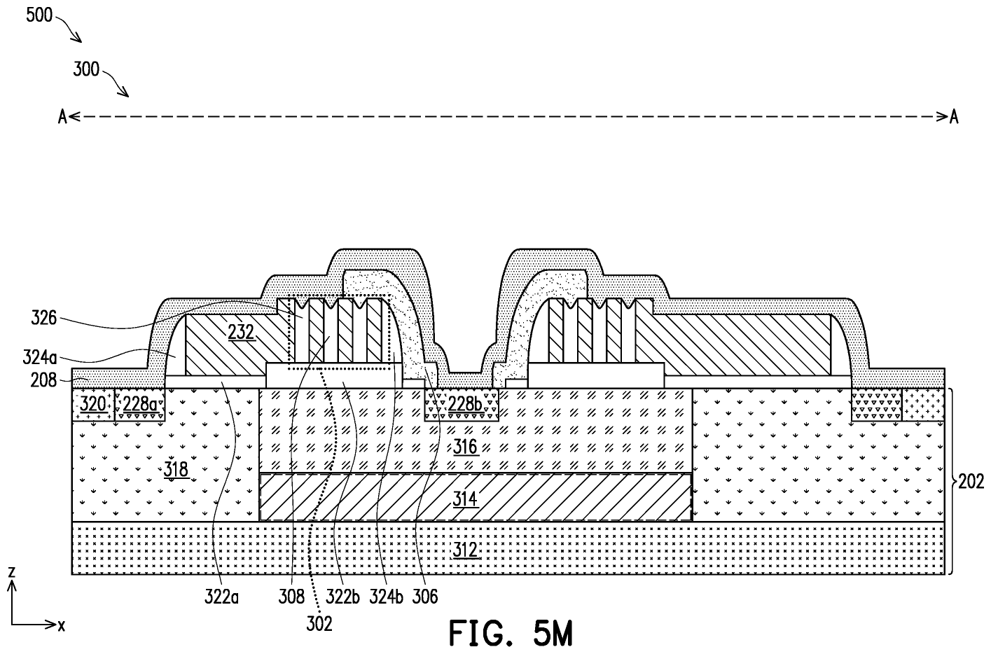

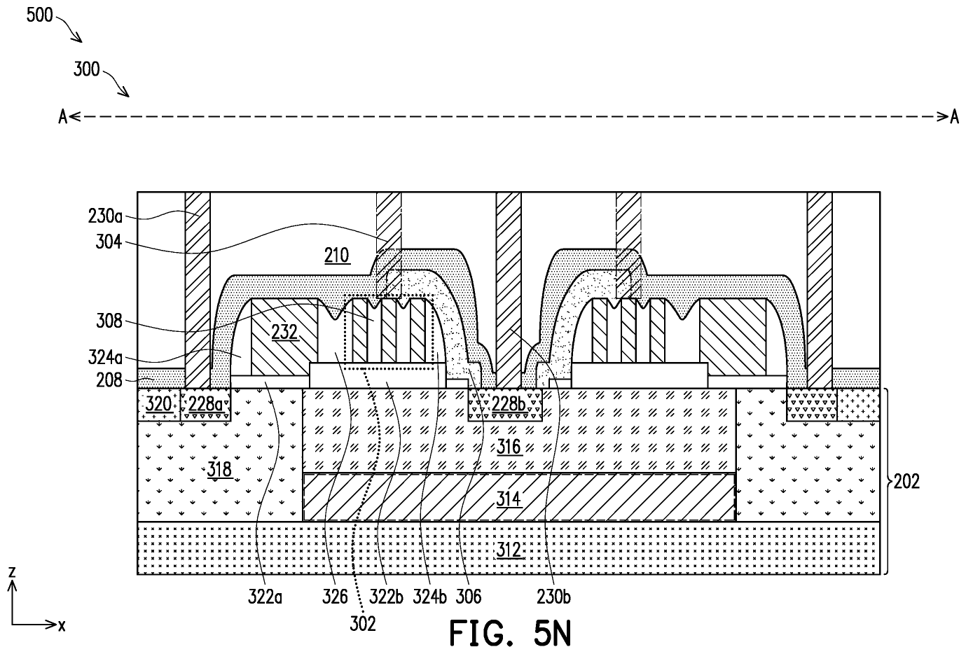

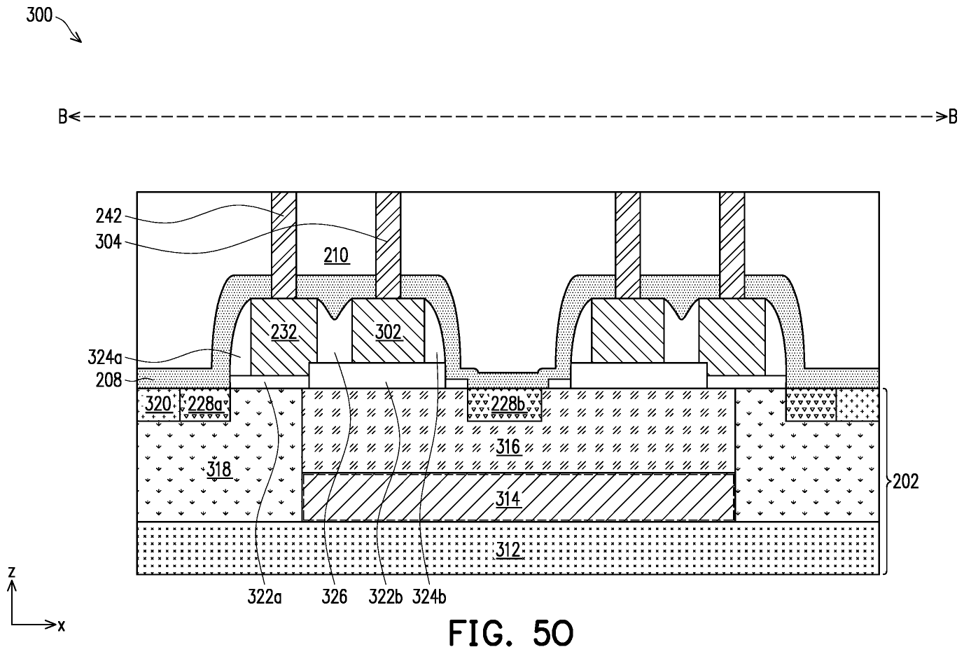

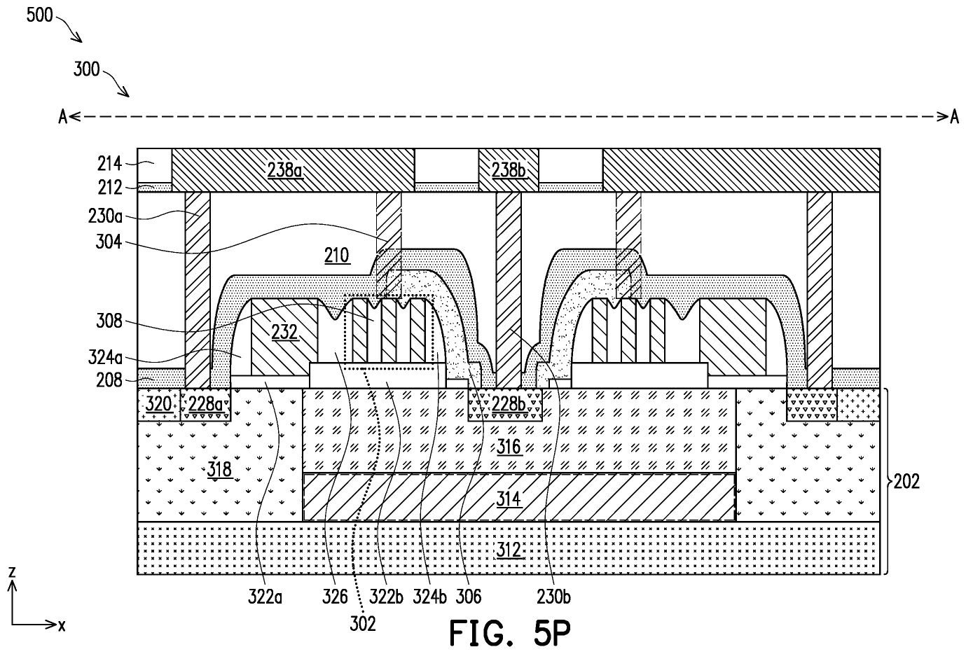

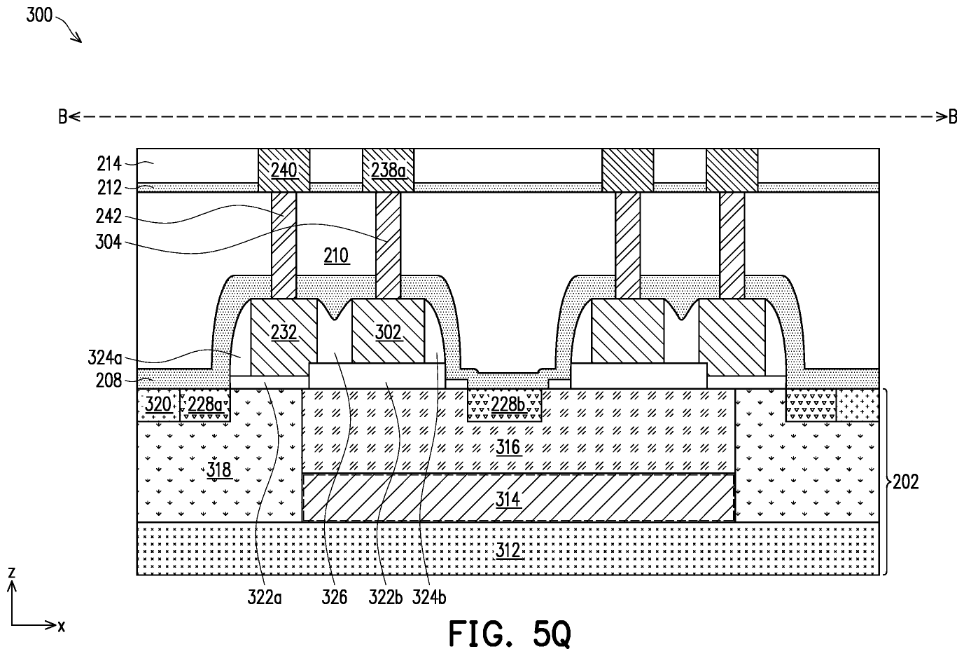

In some implementations, one or more of the semiconductor processing tools 102-114 and/or the wafer/die transport tool 116 may be used to perform one or more semiconductor processing operations described in connection with FIGS. 5A-5Q and/or 8, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

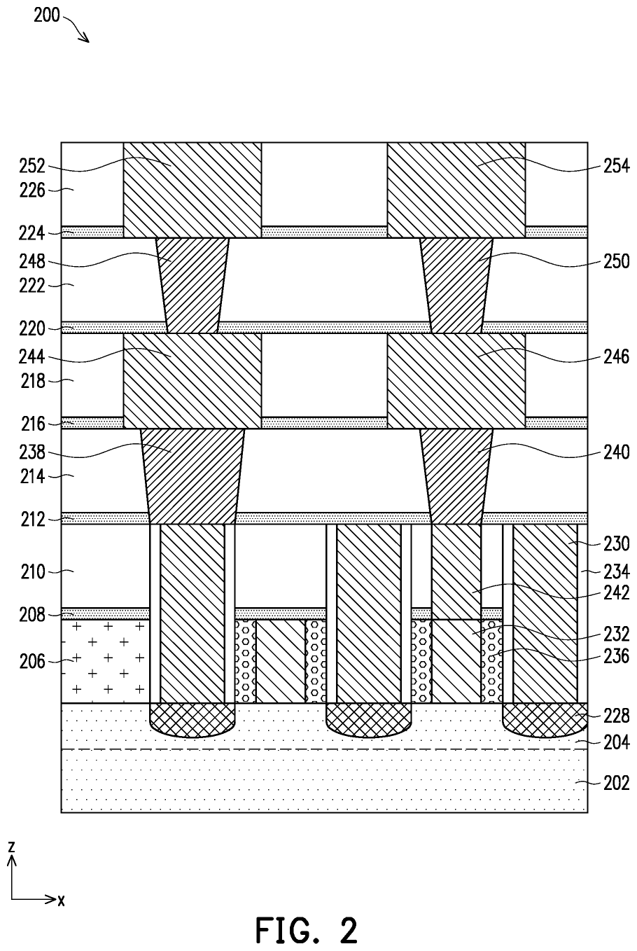

FIG. 2 is a diagram of a portion of an example semiconductor device 200 described herein. The semiconductor device 200 includes an example of a memory device (e.g., a static random access memory (SRAM), a dynamic random access memory (DRAM)), a logic device, a processor, an input/output (I/O) device, or another type of semiconductor device that includes one or more transistors. In some implementations, the semiconductor device 200 includes one or more high-voltage transistors. In these implementations, the semiconductor device 200 may include an integrated circuit (IC) driver, a power IC, an image sensors, a display driver IC (DDIC), a bipolar complementary metal oxide semiconductor (CMOS) diffused metal oxide semiconductor (DMOS) IC (BCD IC), and/or image signal processing (ISP) IC, among other examples.

The semiconductor device 200 includes one or more stacked layers, including a dielectric layer 206, an etch stop layer (ESL) 208, a dielectric layer 210, an ESL 212, a dielectric layer 214, an ESL 216, a dielectric layer 218, an ESL 220, a dielectric layer 222, an ESL 224, and a dielectric layer 226, among other examples. The dielectric layers 206, 210, 214, 218, 222, and 226 are included to electrically isolate various structures of the semiconductor device 200. The dielectric layers 206, 210, 214, 218, 222, and 226 include a silicon nitride (SiNₓ), an oxide (e.g., a silicon oxide (SiOₓ) and/or another oxide material), and/or another type of dielectric material. The ESLs 208, 212, 216, 220, 224 includes a layer of material that is configured to permit various portions of the semiconductor device 200 (or the layers included therein) to be selectively etched or protected from etching to form one or more of the structures included in the semiconductor device 200.

As further shown in FIG. 2, the semiconductor device 200 includes a plurality of source/drain regions 228. Source/drain region(s) may refer to a source or a drain, individually or collectively dependent upon the context. The source/drain regions 228 may include epitaxial (epi) regions that are grown and/or otherwise formed on and/or around portions of the fin structure 204. The source/drain regions 228 may be formed by epitaxial growth and/or another processing technique. In some implementations, the source/drain regions 228 are formed in recessed portions in the fin structure 204. The recessed portions may be formed by strained source drain (SSD) etching of the fin structure 204 and/or another type etching operation. The source/drain regions 228 function as source or drain regions of the transistors included in the semiconductor device 200.

The source/drain regions 228 may include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the semiconductor device 200 may include p-type metal oxide semiconductor (PMOS) transistors that include p-type source/drain regions, n-type metal oxide semiconductor (NMOS) transistors that include n-type source/drain regions, and/or other types of transistors.

The source/drain regions 228 are electrically connected to source/drain contacts 230 of the transistors included in the semiconductor device 200. The source/drain contacts (metal source/drains (MDs)) 230 include cobalt (Co), ruthenium (Ru), and/or another conductive or metal material. The transistors further include gate structures 232 (main gates (MGs)), which are formed of a polysilicon material, a metal (e.g., tungsten (W) or another metal), and/or another type of conductive material. The source/drain contacts 230 and the gate structures 232 are electrically isolated by one or more sidewall spacers, including sidewall spacer layers 234 in each side of the source/drain contacts 230 and sidewall spacer layers 236 on each side of the gate structures 232. The sidewall spacer layers 234 and 236 include a silicon oxide (SiOₓ), a silicon nitride (SiₓN_{y}), a silicon oxy carbide (SiOC), a silicon oxycarbonitride (SiOCN), and/or another suitable material. In some implementations, the sidewall spacer layers 234 are omitted from the sidewalls of the source/drain contacts 230.

As further shown in FIG. 2, the source/drain contacts 230 and the gate structures 232 are electrically connected to one or more types of interconnects. The interconnects electrically connect the transistors of the semiconductor device 200 and/or electrically connect the transistors to other areas and/or components of the semiconductor device 200. In some implementations, the interconnects electrically connect the transistors to a back end of line (BEOL) region of the semiconductor device 200.

The source/drain contacts 230 are electrically connected to interconnects 238. One or more of the gate structures 232 are electrically connected to interconnects 240 (e.g., gate vias or VGs). The interconnects 238 and 240 include a conductive material such as tungsten, cobalt, ruthenium, copper, and/or another type of conductive material. In some implementations, the gate structures 232 are electrically connected to the interconnects 240 by gate contacts 242 (CB or MP) to reduce contact resistance between the gate structures 232 and the interconnects 240. The gate contacts 242 include tungsten (W), cobalt (Co), ruthenium (Ru), titanium (Ti), aluminum (Al), copper (Cu) or gold (Au), among other examples of conductive materials.

As further shown in FIG. 2, the interconnects 238 and 240 are electrically connected to a plurality of BEOL layers, each including one or more metallization layers and/or vias. As an example, the interconnects 238 and 240 may be electrically connected to an MO metallization layer that includes conductive structures 244 and 246. The MO metallization layer is electrically connected to a V0 via layer that includes vias 248 and 250. The V0 via layer is electrically connected to an MI metallization that includes conductive structures 252 and 254. In some implementations, the BEOL layers of the semiconductor device 200 includes additional metallization layers and/or vias that connect the semiconductor device 200 to a package.

As indicated above, FIG. 2 is provided as an example. Other examples may differ from what is described with regard to FIG. 2.

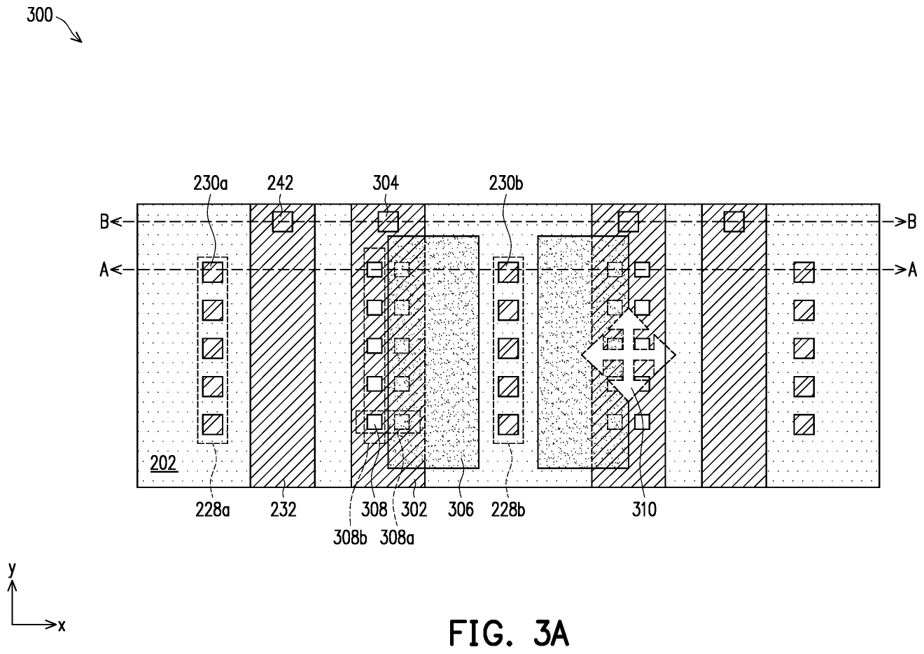

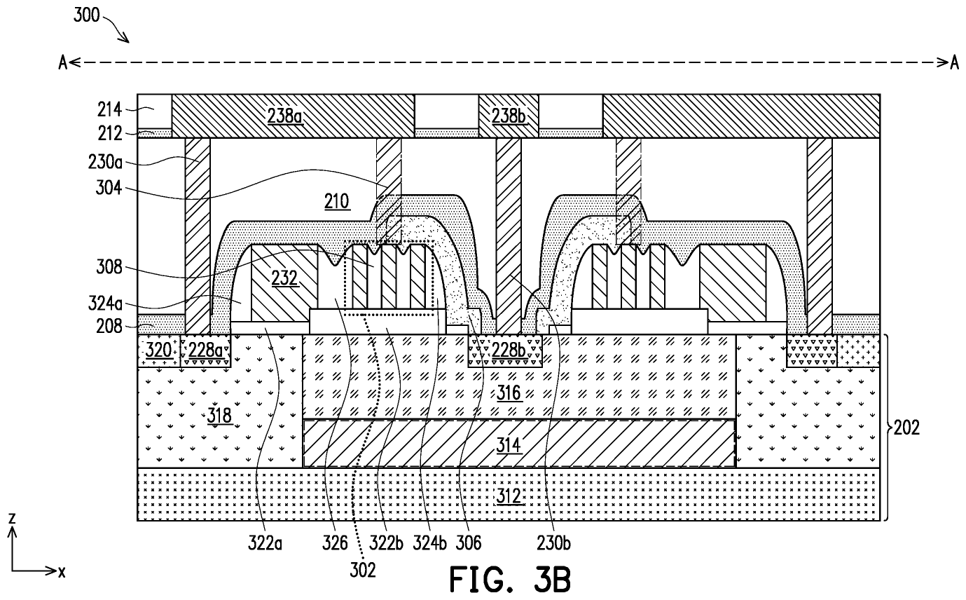

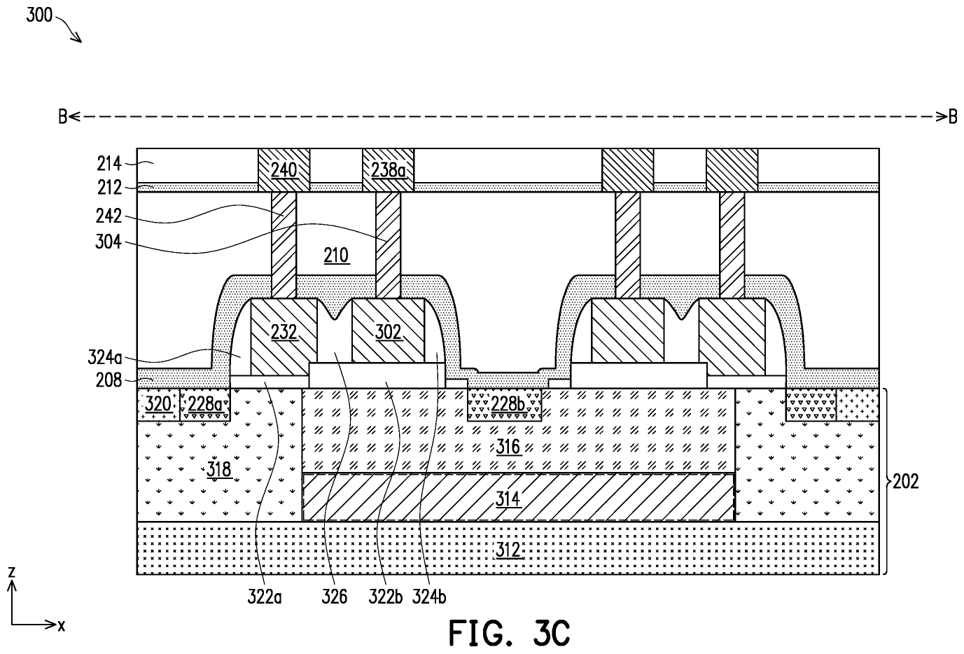

FIGS. 3A-3C are diagrams of an example transistor structure 300 described herein. The transistor structure 300 may be included in the semiconductor device 200 described in connection with FIG. 2. The transistor structure 300 may include a high-voltage transistor, such as a high-voltage planar transistor, a high-voltage fin field effect transistor (FinFET), a high-voltage nanostructure transistor (e.g., a gate all around (GAA) transistor, a nanosheet transistor, a nanotube transistor, a nanoribbon transistor), a high-voltage laterally diffused metal oxide semiconductor (LDMOS) transistor, and/or another type of high-voltage transistor.

FIG. 3A illustrates a top-down view of the transistor structure 300. As shown in FIG. 3A, the transistor structure 300 is included in the substrate 202 of the semiconductor device 200. The transistor structure 300 includes a source/drain region 228a in the substrate 202, and a source/drain region 228b included in the substrate 202. In some implementations, the source/drain region 228a is a source region of the transistor structure 300 and the source/drain region 228b is a drain region of the transistor structure 300 that is configured to operate at a relatively high voltage. As an example, the source/drain region 228b may operate at a drain voltage that is included in a range of approximately 9 volts to approximately 36 volts, whereas a low-voltage transistor might operate in a drain voltage range of approximately 0 volts to approximately 1.8 volts. However, other values for these ranges are within the scope of the present disclosure. In some implementations, the source/drain region 228b is a source region of the transistor structure 300 and the source/drain region 228a is a drain region of the transistor structure 300 that is configured to operate at a relatively high voltage.

The source/drain region 228a may be electrically coupled and/or physically coupled with one or more source/drain contacts 230a above the source/drain region 228a, and the source/drain regions 228b may be electrically coupled and/or physically coupled with one or more source/drain contacts 230b above the source/drain region 228b.

A gate structure 232 may be included over the substrate 202 between the source/drain region 228a and the source/drain region 228b. A voltage may be selectively applied to the gate structure 232 to selectively control the electrical conductivity in the substrate 202 between the source/drain region 228a and the source/drain region 228b. The gate structure 232 may extend in a y-direction in a top-down view of the semiconductor device 200. The gate structure 232 may be electrically coupled and/or physically coupled with one or more gate contacts 242 above the gate structure 232. In some implementations, the gate contact(s) 242 are located at an end of the gate structure 232. However, other locations for the gate contact(s) 242 are within the scope of the present disclosure.

The transistor structure 300 further includes a field plate structure 302 between the gate structure 232 and the source/drain region 228b. The field plate structure 302 enables an electric field between the gate structure 232 and the source/drain region 228b to be manipulated to achieve a particular breakdown voltage for the transistor structure 300. In particular, the field plate structure 302 may be electrically biased during operation of the transistor structure 300 such that the field plate structure 302 suppresses the peak magnitude of the electric field, thereby enabling the transistor structure 300 to be operated at greater operating voltages before reaching breakdown.

The field plate structure 302 includes a polysilicon material, a metal (e.g., tungsten (W) or another metal), and/or another type of electrically conductive material. The field plate structure 302 may include an elongated structure that is approximately parallel with the gate structure 232, and that extends in the y-direction. The dimension of the field plate structure 302 in the x-direction (which is approximately perpendicular to the y-direction) in the semiconductor device 200 is referred to as the length of the field plate structure 302. The length of the field plate structure 302 may be selected to satisfy a breakdown voltage threshold for the transistor structure 300. For example, the length of the field plate structure 302 may be increased to increase the breakdown voltage of the transistor structure 300, or may be decreased to reduce the breakdown voltage of the transistor structure 300.

The field plate structure 302 may be electrically coupled and/or physically coupled with one or more field plate contacts 304 above the field plate structure 302. The field plate contact(s) 304 enable an electrical bias (e.g., a voltage, a current) to be applied to the field plate structure 302 to suppress the electric field between the gate structure 232 and the source/drain region 228b during operation of the transistor structure 300. The electrical bias increases carrier depletion in the substrate 202 between the gate structure 232 and the source/drain region 228b, thereby reducing the peak electric field strength in the substrate 202 between the gate structure 232 and the source/drain region 228b. In some implementations, the field plate contact(s) 304 are located at an end of the field plate structure 302. However, other locations for the field plate contact(s) 304 are within the scope of the present disclosure.

The transistor structure 300 may further include a resist protective oxide (RPO) layer 306 between the gate structure 232 and the source/drain region 228b. The RPO layer 306 may be included over and/or on a portion of the field plate structure 302. The RPO layer 306 may be included to prevent silicide formation on the substrate 202, on the field plate structure 302, and/or on another surface of the transistor structure 300. The RPO layer 306 may include one or more dielectric materials, such as an oxide (e.g., SiOₓ such as SiO₂), a nitride (e.g., SiₓN_{y} such as Si₃N₄), a carbide, an oxynitride, an oxycarbide, and a nitride carbide, a polymer, the like, and/or another suitable dielectric material.

At least one dielectric structure 308 is included in the field plate structure 302. The dielectric structure(s) 308 include dielectric plugs, dielectric columns, and/or another type of dielectric structure(s) that may be arranged in a grid configuration in the top-down view of the transistor structure 300. The grid configurations include a plurality of rows 308a of dielectric structure(s) 308 in the x-direction, and one or more columns 308b of dielectric structure(s) 308 in the y-direction.

The quantity of rows 308a may be included in a range of approximately 5 rows to approximately 200 rows. In some implementations, the quantity of rows 308a is included in a range of approximately 9 rows to approximately 199 rows, depending on a y-direction width of the field plate structure 302. For example, the greater the y-direction width of the field plate structure 302 (and the greater the output current of the transistor structure 300), the greater the quantity of rows 308a of dielectric structure(s) 308 that may be included in the field plate structure 302. Conversely, the lesser the y-direction width of the field plate structure 302 (and the lesser the output current of the transistor structure 300), the lesser the quantity of rows 308a of dielectric structure(s) 308 that may be included in the field plate structure 302. However, other ranges for the quantity of rows 308a are within the scope of the present disclosure.

The quantity of columns 308b may be included in a range of approximately 1 row to approximately 4 rows, depending on the x-direction length of the field plate structure 302. For example, the greater the x-direction length of the field plate structure 302 (and the greater the operating voltage of the transistor structure 300), the greater the quantity of columns 308b of dielectric structure(s) 308 that may be included in the field plate structure 302. Conversely, the lesser the x-direction length of the field plate structure 302 (and the lesser the output current of the transistor structure 300), the lesser the quantity of columns 308b of dielectric structure(s) 308 that may be included in the field plate structure 302. However, other ranges for the quantity of columns 308b are within the scope of the present disclosure.

The dielectric structure(s) 308 are included to enable the distance between the gate structure 232 and the field plate structure 302 to be less than if the dielectric structure(s) 308 were not included. As described in greater detail in connection with FIGS. 5F and 5G, by including the dielectric structure(s) 308 in the field plate structure 302, a feature density in a pattern that is used to form the gate structure 232, the field plate structure 302, and recesses through the field plate structure 302 for the dielectric structure(s) 308 is increased such that the pattern is a densely populated pattern. The densely populated pattern enables a greater amount of luminous flux to be exposed to the underlying photoresist in which the pattern is formed. The greater amount of luminous flux enables the gate structure 232 and the field plate structure 302 to be spaced closer together while still permitting a sufficient amount of luminous flux to reach the photoresist to ensure full development of the pattern.

The arrangement of the dielectric structure(s) 308 in the field plate structure 302 provides regions of the field plate structure 302 that fully extend between opposing sides of the field plate structure 302 in the x-direction, and regions of the field plate structure 302 that fully extend between opposing ends of the field plate structure 302 in the y-direction. This enables the field plate structure 302 to provide a reduced surface field (RESURF) effect 310 in both the x-direction and in the y-direction, which enables the field plate structure 302 to be used to suppress the electric field between the gate structure 232 and the source/drain regions 228b in both the x-direction and in the y-direction.

FIG. 3B illustrates a cross-section view of the transistor structure 300 along the line A-A in FIG. 3A. As shown in FIG. 3B, the substrate 202 may include a plurality of regions. An n-type region 312 includes a region of the substrate 202 that is doped with one or more n-type dopants, such as phosphorous (P) or arsenic (As), among other examples. The n-type region 312 may be referred to as an n-type buried layer (NBL). A deep p-well (DPW) region 314 may be included above the n-type region 312. The DPW region 314 includes a region of the substrate 202 that is doped with one or more p-type dopants, such as boron (B) or germanium (Ge), among other examples. A drift region 316 may be included above the DPW region 314. The drift region 316 may include a region of the substrate 202 that is doped with one or more n-type dopants. The drift region 316 includes a portion of the substrate 202 between the gate structure 232 and the source/drain region 228b. The drift region 316 is located under the field plate structure 302, which enables the field plate structure 302 to be used to control the electric field in the drift region 316 of the substrate 202. A channel region 318 may be located adjacent to the DPW region 314 and the drift region 316. The channel region 318 may include a portion of the substrate 202 that is doped with one or more p-type dopants. The channel region 318 includes a portion of the substrate 202 under the gate structure 232. An isolation region 320 may be located adjacent to the source/drain region 228a in the substrate 202. The isolation region 320 includes a portion of the substrate 202 that is doped with one or more p-type dopants.

The source/drain regions 228a and 228b may be included in the substrate 202. The gate structure 232 and the field plate structure 302 may be included above the substrate 202 and between the source/drain regions 228a and 228b. The gate structure 232 and the field plate structure 302 may be covered by an ESL 208 and a dielectric layer 210. The source/drain contact 230a may extend through the dielectric layer 210 and may be coupled with the source/drain region 228a. The source/drain contact 230b may extend through the dielectric layer 210 and may be coupled with the source/drain region 228b. The field plate contact 304 may extend through the dielectric layer 210 and may be coupled with the field plate structure 302.

An ESL 212 is included above the dielectric layer 210, and a dielectric layer 214 is included above the ESL. Interconnects 238a and 238b may be included in the dielectric layer 214 and/or in the ESL 212, with the interconnect 238a being electrically coupled and/or physically coupled with the source/drain contact 230a, and the interconnect 238b being electrically coupled and/or physically coupled with the source/drain contact 230b. The field plate contact 304 is illustrated in FIG. 3B in broken lines to indicate that the field plate contact 304 is not visible in the cross-section along line A-A. The field plate contact 304 is included in FIG. 3B to illustrate that the interconnect 238a electrically couples the source/drain region 228a and the field plate structure 302 through the source/drain contact 230a and the field plate contact 304. This enables the field plate structure 302 to be source biased. Source biasing the field plate structure 302 may transform a gate-drain charge (Q_{gd}) portion of the electric field in the substrate 202 to be a drain-source charge (Q_{ds}), which may reduce the gate-drain charge (Q_{gd}) of the electric field so the transistor structure 300 can be operated at higher frequencies with lower switching power loss.

A gate dielectric layer 322a is included on the substrate 202 between the substrate 202 and the gate structure 232. The gate dielectric layer 322a may provide electrical isolation between the gate structure 232 and the substrate 202, which enables a voltage applied to the gate structure 232 to cause an electric field to be generated in the substrate 202. A field plate dielectric layer 322b is included on the substrate 202 between the substrate 202 and the field plate structure 302. The field plate dielectric layer 322b may provide electrical isolation between the field plate structure 302 and the substrate 202, which enables a voltage to be applied to the field plate structure 302 to suppress the electric field in the drift region 316 generated by the gate structure 232. The dielectric structure(s) 308 continuously extend between a top surface of the field plate structure 302 and a bottom surface of the field plate structure 302. Thus, the bottom surfaces of the dielectric structure(s) 308 may be in contact with a top surface of the field plate dielectric layer 322b.

The gate dielectric layer 322a and the field plate dielectric layer 322b may each include a silicon nitride (SiNₓ), an oxide (e.g., a silicon oxide (SiOₓ) and/or another oxide material), and/or another type of dielectric material. In some implementations, a z-direction thickness of the field plate dielectric layer 322b is greater than a z-direction thickness of the gate dielectric layer 322a. In some implementations, the z-direction thickness of the field plate dielectric layer 322b and the z-direction thickness of the gate dielectric layer 322a are approximately a same thickness. In some implementations, a portion of the gate structure 232 is included on a portion of the field plate dielectric layer 322b.

One or more sidewall spacers are included over and/or on sidewalls of the gate structure 232 and/or over and/or on sidewalls of the field plate structure 302. An outer sidewall spacer 324a is included on an outer sidewall of the gate structure 232 (e.g., the sidewall of the gate structure 232 facing away from the field plate structure 302 and toward the source/drain region 228a). An outer sidewall spacer 324b is included on an outer sidewall of the field plate structure 302 (e.g., the sidewall of the field plate structure 302 facing away from the gate structure 232 and toward the source/drain region 228b). An inner sidewall spacer 326 is included on the inner sidewalls of the gate structure 232 and the field plate structure 302.

The inner sidewall spacer 326 is a merged sidewall spacer that continuously extends between the inner sidewalls of the gate structure 232 and the field plate structure 302. Because of this, the RPO layer 306 can be omitted from the gate structure 232 and can be included on less than an entirety of the x-direction length of the field plate structure 302. Instead, the inner sidewall spacer 326 provides the protection against silicide formation between the gate structure 232 and the field plate structure 302. The inner sidewall spacer 326 also provides electrical isolation between the gate structure 232 and the field plate structure 302, which reduces the likelihood of electrical shorting between the gate structure 232 and the field plate structure 302.

The continuity of the inner sidewall spacer 326, such that the inner sidewall spacer 326 is shared by the gate structure 232 and the field plate structure 302, is achieved by the reduced distance between the gate structure 232 and the field plate structure 302 that is enabled by the inclusion of the dielectric structure(s) 308 in the field plate structure. If the gate structure 232 and the field plate structure 302 were positioned further apart, the sidewall spacers formed on the inner sidewalls of the gate structure 232 and the field plate structure 302 would otherwise not merge into a single inner sidewall spacer 326. Thus, the RPO layer 306 would otherwise need to remain between the gate structure 232 and the field plate structure 302 to provide the silicide formation protection and/or the electrical isolation between the gate structure 232 and the field plate structure 302. Thus, the dielectric structure(s) 308 enable fewer layers to be included above the gate structure 232, which may enable a lesser gate resistance to be achieved for the transistor structure 300.

The outer sidewall spacers 324a and 324b, and the inner sidewall spacer 326, may each include silicon oxycarbide (SiOC), a silicon nitride (SiNₓ), an oxide (e.g., a silicon oxide (SiOₓ) and/or another oxide material), and/or another suitable dielectric material. In some implementations, the outer sidewall spacers 324a and 324b, the inner sidewall spacer 326, and the dielectric structure(s) 308 include the same dielectric material or the same combination of dielectric materials. In some implementations, the outer sidewall spacers 324a and 324b, the inner sidewall spacer 326, and/or the dielectric structure(s) 308 include different dielectric materials or different combinations of dielectric materials.

The RPO layer 306 is included over a portion of a top surface of the field plate structure 302 and on the outer sidewall spacer 324b that is on the outer sidewall of the field plate structure 302. The RPO layer 306 is located between the field plate structure 302 and the source/drain region 228b. A first end of the RPO layer 306 may be located between adjacent columns 308b (e.g., between a first column 308b and a second column 308b) of the dielectric structure(s) 308. Thus, the RPO layer 306 may be included over only a subset of the dielectric structure(s) 308. A second end of the RPO layer 306 may be located adjacent to the source/drain region 228b.

FIG. 3C illustrates a cross-section view of the transistor structure 300 along the line B-B in FIG. 3A. As shown in FIG. 3C, a gate contact 242 is included on the gate structure 232, and an interconnect 240 is included on the gate structure. The field plate contact 304 is included on the field plate structure 302, and the interconnect 238a is included on the field plate contact 304.

As indicated above, FIGS. 3A-3C are provided as an example. Other examples may differ from what is described with regard to FIGS. 3A-3C.

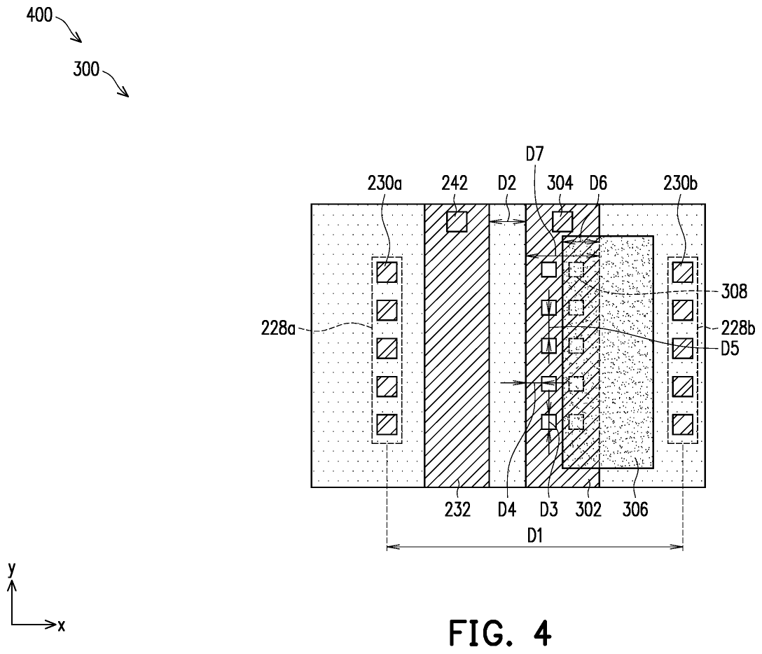

FIG. 4 is a diagram of an example implementation 400 of a transistor structure 300 described herein. In particular, FIG. 4 illustrates one or more dimensions of the transistor structure 300 described herein. As shown in FIG. 4, an example dimension D1 of the transistor structure 300 includes a device pitch of the transistor structure 300. “Device pitch” refers to the distance between the source/drain region 228a and the source/drain region 228b. In some implementations, the dimension D1 is approximately 0.8 microns to 4 microns. This range for the device pitch of the transistor structure 300 (and lesser device pitches) may be achieved through the inclusion of the dielectric structure(s) 308 in the field plate structure 302 because of the reduced distance between the field plate structure 302 and the gate structure 232 that is achievable by the inclusion of the dielectric structure(s) 308. However, other values for the range are within the scope of the present disclosure.

As further shown in FIG. 4, another example dimension D2 of the transistor structure 300 includes a distance between the gate structure 232 and the field plate structure 302. In some implementations, the dielectric structure(s) 308 in the field plate structure 302 enable a distance between the field plate structure 302 and the gate structure 232 of approximately 0.10 microns or less. This enables a high density of transistor structures 300 to be included in the semiconductor device 200 and/or enables a low R_{dson} to be achieved for the transistor structure 300. Moreover, the shorter the distance between the gate structure 232 and the field plate structure 302, the greater the control that the field plate structure 302 may exert over the electric field generated by the gate structure 232. Thus, the distance between the field plate structure 302 and the gate structure 232 of approximately 0.10 microns or less enables greater control over the electric field generated by the gate structure 232 than without the dielectric structure(s) 308. However, other values for the dimension D2 are within the scope of the present disclosure.

As further shown in FIG. 4, another example dimension D3 of the transistor structure 300 includes a width of a dielectric structure 308. In some implementations, the dimension D3 is included in a range of approximately 0.09 microns to approximately 0.11 microns. If the dimension D3 is less than approximately 0.09 microns, the field plate structure 302 may be unable to be patterned using photolithography techniques to form openings through the field plate structure 302 in which the dielectric structure(s) 308 are formed. If the dimension D3 is greater than approximately 0.11 microns, the openings in which the dielectric structure(s) 308 are formed may be too large to fully fill with the dielectric structure(s) 308, which may result in an increased likelihood of the underlying field plate dielectric layer 322b being etched during etching of the RPO layer 306. This may result in silicide formation in the openings, which may result in Schottky leakage in the transistor structure 300. The dimension D3 may be included in the range of approximately 0.09 microns to approximately 0.11 microns to satisfy a photolithography patterning parameter for the dielectric structure(s) 308 while ensuring that the openings through the field plate structure 302 are fully filled with the dielectric structure(s) 308. However, other values for the dimension D3, and ranges other than approximately 0.09 microns to approximately 0.11 microns are included in the scope of the present disclosure.

As further shown in FIG. 4, another example dimension D4 of the transistor structure 300 includes a distance between a side of the field plate structure 302 and a side of a dielectric structure 308. In some implementations, the dimension D4 is included in a range of approximately 0.03 microns to approximately 0.045 microns. If the dimension D4 is less than approximately 0.03 microns, the field plate structure 302 may be unable to be patterned using photolithography techniques to form openings through the field plate structure 302 in which the dielectric structure(s) 308 are formed. If the dimension D4 is greater than approximately 0.045 microns, the device pitch of the transistor structure 300 may be too large to enable a high density of transistor structures 300 to be included in the semiconductor device 200. The dimension D4 may be included in the range of approximately 0.03 microns to approximately 0.045 microns to satisfy a photolithography patterning parameter for the dielectric structure(s) 308 while enabling a sufficiently low device pitch for the transistor structure 300 to be achieved. However, other values for the dimension D4, and ranges other than approximately 0.03 microns to approximately 0.045 microns are included in the scope of the present disclosure.

As further shown in FIG. 4, an example dimension D5 of the transistor structure includes a distance between adjacent dielectric structure(s) 308. In some implementations, the dimension D5 is included in a range of approximately 0.25 microns to approximately 0.50 microns to satisfy a photolithography patterning parameter for the dielectric structure(s) 308. However, other values for the range are within the scope of the present disclosure.

As further shown in FIG. 4, an example dimension D6 of the transistor structure 300 includes an amount of overlap of the field plate structure 302 by the RPO layer 306 in the x-direction. The amount of overlap of the field plate structure 302 by the RPO layer 306 may be less than the entirety of an x-direction length (indicated in FIG. 4 as dimension D7). In some implementations, the dimension D6 is included in a range of approximately 0.06 microns to approximately 0.14 microns. If the dimension D6 is less than approximately 0.06 microns, defects may occur in the RPO layer 306 because of insufficient photoresist pattern resolution for patterning the RPO layer 306. If the dimension D6 is greater than approximately 0.14 microns, the gate resistance for gate structure 232 of the transistor structure 300 may not satisfy a gate resistance threshold. If the dimension D6 is included in the range of approximately 0.06 microns to approximately 0.14 microns, the likelihood of defect formation in the RPO layer 306 and the gate resistance for the gate structure 232 may be reduced. However, other values for the dimension D6, and ranges other than approximately 0.06 microns to approximately 0.14 microns are included in the scope of the present disclosure.

As indicated above, FIG. 4 is provided as an example. Other examples may differ from what is described with regard to FIG. 4.

FIGS. 5A-5Q are diagrams of an example implementation 500 of forming a transistor structure 300 described herein. In some implementations, one or more of the operations described in connection with FIGS. 5A-5Q are performed using one or more of the semiconductor processing tools 102-114. In some implementations, one or more of the operations described in connection with FIGS. 5A-5Q are performed using another semiconductor processing tool.

Turning to FIG. 5A, the substrate 202 may be provided. The substrate 202 may be provided as a semiconductor wafer, a semiconductor die, and/or another type of semiconductor substrate. In some implementations, the substrate 202 may be a doped substrate, such as a semiconductor substrate that is doped with one or more p-type dopants, a semiconductor substrate that is doped with one or more n-type dopants, and/or another type of doped substrate. In some implementations, the substrate 202 has a bulk resistivity (or volumetric resistivity) that is included in a range of approximately 1 ohm-centimeter to approximately 100 ohm-centimeters. However, other values for the range are within the scope of the present disclosure.

As further shown in FIG. 5A, one or more regions of the substrate 202 may be doped. For example, the n-type region 312 may be formed in the substrate 202. As another example, the DPW region 314 may be formed above the n-type region 312 in the substrate 202. As another example, the drift region 316 may be formed above the DPW region 314 in the substrate 202. In some implementations, the substrate 202 may be provided as a p-type substrate or an n-type substrate, and the channel region 318 may be a portion of the p-type substrate or the n-type substrate. Alternatively, the n-type region 312 may be a p-type region and the DPW region 314 may be a deep n-well (DNW) region.

In some implementations, the ion implantation tool 114 may be used to form the n-type region 312 by performing an ion implantation operation to implant ions (e.g., n-type ions) into the substrate 202 to form the n-type region 312. The ion implantation tool 114 may be used to direct an ion beam toward the substrate 202 such that the ions are implanted below the surface of the substrate 202 to dope the substrate 202. Additionally and/or alternatively, the deposition tool 102 may deposit the n-type region 312 in a PVD operation, an ALD operation, a CVD operation, an epitaxy operation, an oxidation operation, another type of deposition operation described in connection with FIG. 1, and/or another suitable deposition operation.

In some implementations, the ion implantation tool 114 may be used to form the DPW region 314 by performing an ion implantation operation to implant ions (e.g., p-type ions) into the substrate 202 to form the DPW region 314. The ion implantation tool 114 may be used to direct an ion beam toward the substrate 202 such that the ions are implanted below the surface of the substrate 202 to dope the substrate 202. Additionally and/or alternatively, the deposition tool 102 may deposit the DPW region 314 in a PVD operation, an ALD operation, a CVD operation, an epitaxy operation, an oxidation operation, another type of deposition operation described in connection with FIG. 1, and/or another suitable deposition operation.

In some implementations, the ion implantation tool 114 may be used to form the drift region 316 by performing an ion implantation operation to implant ions (e.g., n-type ions) into the substrate 202 to form the drift region 316. The ion implantation tool 114 may be used to direct an ion beam toward the substrate 202 such that the ions are implanted below the surface of the substrate 202 to dope the substrate 202. Additionally and/or alternatively, the deposition tool 102 may deposit the drift region 316 in a PVD operation, an ALD operation, a CVD operation, an epitaxy operation, an oxidation operation, another type of deposition operation described in connection with FIG. 1, and/or another suitable deposition operation.

As shown in FIG. 5B, a dielectric layer 502 may be formed over and/or on the top surface of the substrate 202. A deposition tool 102 may be used to deposit the dielectric layer 502 using a PVD technique, an ALD technique, a CVD technique, a spin-coating technique, an oxidation technique (e.g., a high-temperature thermal oxidation technique), another type of deposition technique described in connection with FIG. 1, and/or another suitable deposition technique. In some implementations, the planarization tool 110 planarizes the dielectric layer 502 after the deposition tool 102 deposits the dielectric layer 502.

As shown in FIG. 5C, portions of the dielectric layer 502 are removed, and remaining portions of the dielectric layer 502 correspond to the field plate dielectric layer 322b on the drift region 316. In some implementations, a pattern in a photoresist layer is used to etch the dielectric layer 502 to form the field plate dielectric layer 322b. In these implementations, a deposition tool 102 may be used to form the photoresist layer on the dielectric layer 502. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the dielectric layer 502 based on the pattern to form the field plate dielectric layer 322b from the dielectric layer 502. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 502 based on a pattern.

As shown in FIG. 5D, the gate dielectric layer 322a may be formed on the substrate 202 and adjacent to the field plate dielectric layer 322b. The gate dielectric layer 322a may be formed in a similar manner as the field plate dielectric layer 322b described above. A dielectric layer may be deposited (e.g., using a deposition tool 102) on the substrate 202 and on the field plate dielectric layer 322b, and an etch tool 108 may be used to remove portions of the dielectric layer on the field plate dielectric layer 322b based on a pattern such that remaining portions of the dielectric layer on the substrate remain as the gate dielectric layer 322a.

As shown in FIG. 5E, a layer 504 of gate material is formed over the gate dielectric layer 322a and over the field plate dielectric layer 322b. A deposition tool 102 and/or a plating tool 112 may be used to deposit the layer 504 of gate material using a CVD technique, a PVD technique, an ALD technique, an electroplating technique, another deposition technique described above in connection with FIG. 1, and/or another suitable deposition technique. The layer 504 of gate material may have a plurality of sections across the substrate 202 that have z-direction heights. For example, a section of the layer 504 of gate material on the field plate dielectric layer 322b may have a greater z-direction height than a section of the layer 504 of gate material on the gate dielectric layer 322a because of the z-direction thickness of the field plate dielectric layer 322b being greater than the z-direction thickness of the gate dielectric layer 322a.

As shown in FIGS. 5F-5H, portions of the layer 504 of gate material may be removed such that remaining portions of the layer 504 of gate material correspond to the gate structure 232 and the field plate structure 302. As shown in FIGS. 5F and 5G, a patterned photoresist layer 506 may be used to etch the layer 504 of gate material to remove the portions of the layer 504 of gate material. A hard mask layer 508 may also be formed on the layer 504 of gate material to facilitate etching of the layer 504 of gate material based on the patterned photoresist layer 506. A deposition tool 102 may be used to deposit a layer of photoresist material on the hard mask layer 508, an exposure tool 104 may be used to transfer a pattern from a photomask 510 to the layer of photoresist material, and a developer tool 106 may be used to develop the pattern in the layer of the photoresist material to form the patterned photoresist layer 506.

As described above, by including the dielectric structure(s) 308 in the field plate structure 302, the feature density in the pattern photoresist layer 506 that is used to etch the layer 504 of gate material is increased (e.g., relative to not including the dielectric structure(s) 308) such that the pattern photoresist layer 506 includes a densely populated pattern. The densely populated pattern enables a greater amount of luminous flux to be exposed to the layer of photoresist material, which enables the gate structure 232 and the field plate structure 302 to be positioned closer together while increasing the likelihood of the patterned photoresist layer 506 being fully developed using the developer tool 106. The increased likelihood of the patterned photoresist layer 506 being fully developed reduces the likelihood of residual photoresist material remaining on the layer 504 of gate material, which reduces the likelihood of defects to occur in etching the layer 504 of gate material.

As shown in FIG. 5H, the gate structure 232 is formed on the gate dielectric layer 322a and, in some implementations, on a portion of the field plate dielectric layer 322b. The field plate structure 302 is formed on the field plate dielectric layer 322b. The patterned photoresist layer 506 is used to form openings 512 through the field plate structure 302 in which the dielectric structure(s) 308 are to be formed. The patterned photoresist layer 506 is also used to form a gap 514 between the gate structure 232 and the field plate structure 302 such that the gate structure 232 and the field plate structure 302 are physically separated.

As shown in FIG. 5I, offset spacers 516 may be formed on sidewalls of the gate structure 232, on sidewalls of the field plate structure 302, on sidewalls of the openings 512 through the field plate structure 302, and on sidewalls of the gap 514 between the gate structure 232 and the field plate structure 302. A deposition tool 102 may be used to deposit a conformal layer of dielectric material using a PVD technique, an ALD technique, a CVD technique, a spin-coating technique, an oxidation technique (e.g., a high-temperature thermal oxidation technique), another type of deposition technique described in connection with FIG. 1, and/or another suitable deposition technique. An etch tool 108 may be used to remove portions of the conformal layer of dielectric material such that remaining portions of the conformal layer of dielectric material remain on sidewalls of the gate structure 232, on sidewalls of the field plate structure 302, on sidewalls of the openings 512 through the field plate structure 302, and on sidewalls of the gap 514 between the gate structure 232 and the field plate structure 302.

As shown in FIG. 5J, the outer sidewall spacer 324a may be formed on the outer sidewall of the gate structure 232, the outer sidewall spacer 324b may be formed on the outer sidewall of the field plate structure 302, and the inner sidewall spacer 326 may be formed on the inner sidewalls of the gate structure 232 and the field plate structure 302. The outer sidewalls spacers 324a and 324b, and the inner sidewall spacer 326 may be formed on the offset spacers 516. The inner sidewall spacer 326 fills in the gap 514 between the gate structure 232 and the field plate structure 302 such that the inner sidewall spacer 326 is a merged sidewall spacer. The dielectric structure(s) 308 are also formed in the openings 512 through the field plate structure 302. The dielectric structure(s) 308 may be formed on the offset spacers 516 in the openings 512, and may fill the openings 512.

The outer sidewall spacers 324a and 324b, the inner sidewall spacers 326, and the dielectric structure(s) 308 may be formed from a dielectric layer that is deposited over the transistor structure 300. A deposition tool 102 may be used to deposit the dielectric material using a PVD technique, an ALD technique, a CVD technique, a spin-coating technique, an oxidation technique (e.g., a high-temperature thermal oxidation technique), another type of deposition technique described in connection with FIG. 1, and/or another suitable deposition technique. An etch tool 108 may be used to remove portions of the dielectric layer such that remaining portions of the dielectric layer remain on the outer sidewall of the gate structure 232 as the outer sidewall spacer 324a, on the outer sidewall of the field plate structure 302 as the outer sidewall spacer 324b, in the openings 512 as the dielectric structure(s) 308, and on the inner sidewalls of the gate structure 232 and the field plate structure 302 in the gap 514 as the inner sidewall spacer 326. The outer sidewall spacers 324a and 324b may have a concave outer surface as a result of the etching, and the dielectric structure(s) 308 and the inner sidewall spacer 326 may have concave top surfaces as a result of the etching.

As shown in FIG. 5K, one or more isolation regions 320 may be formed in the substrate 202. Forming the one or more isolation regions 320 may include doping the substrate 202 with a p-type dopant or an n-type dopant using an ion implantation tool 114. The source/drain region 228a may be formed adjacent to a first side of the gate structure 232 (e.g., a side opposing the side facing the field plate structure 302), and a source/drain region 228b may be formed adjacent to a side of the field plate structure 302 (e.g., a side opposing the side facing the gate structure 232). Forming the source/drain regions 228a and 228b may include doping the substrate 202 with a p-type dopant or an n-type dopant using an ion implantation tool 114.

As shown in FIG. 5L, the RPO layer 306 is formed on the outer sidewall spacer 324b that is on the outer sidewall of the field plate structure 302. Moreover, the RPO layer 306 is formed on a portion of a top surface of the field plate structure 302. A deposition tool 102 may be used to deposit the RPO layer 306 using a CVD technique, an ALD technique, a PVD technique, and/or another type of deposition technique. In some implementations, the deposition tool 102 deposits the RPO layer 306 as a blanket layer that covers the transistor structure 300. The RPO layer 306 initially covers the gate structure 232 and the field plate structure 302, among other structures and layers of the transistor structure 300. An etch tool 108 may subsequently be used to remove portions of the RPO layer 306 from the gate structure 232 (e.g., so that the RPO layer 306 is no longer on the gate structure 232) and from a portion of the field plate structure 302 such that the RPO layer 306 remains on less than an entirety of the field plate structure 302.

As shown in FIG. 5M, the ESL 208 may be formed over and/or on the transistor structure 300. The ESL 208 covers the source/drain regions 228a and 228b, the gate structure 232, the field plate structure 302, and the RPO layer 306, among other examples. A deposition tool 102 may be used to conformally deposit the ESL 208 using a CVD technique, an ALD technique, a PVD technique, and/or another type of deposition technique.

As shown in FIGS. 5N and 5O, the dielectric layer 210 may be deposited over the ESL 208. A deposition tool 102 may be used to deposit the dielectric layer 210 using a CVD technique, an ALD technique, a PVD technique, and/or another type of deposition technique. In some implementations, a planarization tool 110 is used to planarize the dielectric layer 210 after the dielectric layer 210 is deposited.

As further shown in FIGS. 5N and 5O, the source/drain contacts 230a and 230b, the gate contact 242, and the field plate contact 304 may be formed in the dielectric layer 210 and through the ESL 208. The source/drain contact 230a may be formed on the source/drain region 228a, the source/drain contact 230b may be formed the source/drain region 228b, the gate contact 242 may be formed on the gate structure 232, and the field plate contact 304 may be formed on the field plate structure 302.

To form the source/drain contacts 230a and 230b, the gate contact 242, and the field plate contact 304, recesses may be formed in the dielectric layer 210 and through the ESL 208. The recesses may be formed over the source/drain regions 228a and 228b, over the gate structure 232, and over the field plate structure 302 such that the source/drain regions 228a and 228b, the gate structure 232, and the field plate structure 302 are exposed through the recesses. In some implementations, a pattern in a photoresist layer is used to etch the dielectric layer 210 and the ESL 208 to form the recesses. In these implementations, a deposition tool 102 may be used to form the photoresist layer on the dielectric layer 210. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the dielectric layer 210 and the ESL 208 based on the pattern to form the recesses. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 210 and the ESL 208 based on a pattern.

A deposition tool 102 and/or a plating tool 110 may be used to deposit the source/drain contacts 230a and 230b, the gate contact 242, and the field plate contact 304 in the recesses using a CVD technique, a PVD technique, an ALD technique, an electroplating technique, another deposition technique described above in connection with FIG. 1, and/or another suitable deposition technique. In some implementations, a planarization tool 110 is used to planarize the source/drain contacts 230a and 230b, the gate contact 242, and/or the field plate contact 304 after the source/drain contacts 230a and 230b, the gate contact 242, and/or the field plate contact 304 are deposited.

As shown in FIGS. 5P and 5Q, the ESL 212 may be formed on the dielectric layer 210, and the dielectric layer 214 may be formed on the ESL 212. A deposition tool 102 may be used to deposit the ESL 212 and the dielectric layer 214 using a CVD technique, an ALD technique, a PVD technique, and/or another type of deposition technique. In some implementations, a planarization tool 110 is used to planarize the ESL 212 and/or the dielectric layer 214 after the ESL 212 and/or the dielectric layer 214 are deposited.

As further shown in FIGS. 5P and 5Q, the interconnects 238a, 238b, and 240 may be formed in the dielectric layer 214 and through the ESL 212. The interconnect 238a may be formed on the source/drain contact 230a and on the field plate contact 304 (e.g., such that the source/drain region 228a and the field plate structure 302 are electrically coupled). The interconnect 238b may be formed on the source/drain contact 230b. The interconnect 240 may be formed on the gate contact 242.

To form the interconnects 238a, 238b, and 240, recesses may be formed in the dielectric layer 214 and through the ESL 212. The recesses may be formed over the source/drain contacts 230a and 230b, over the gate contact 242, and over the field plate contact 304 such that the source/drain contacts 230a and 230b, the gate contact 242, and the field plate contact 304 are exposed through the recesses. In some implementations, a pattern in a photoresist layer is used to etch the dielectric layer 214 and the ESL 212 to form the recesses. In these implementations, a deposition tool 102 may be used to form the photoresist layer on the dielectric layer 214. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the dielectric layer 214 and the ESL 212 based on the pattern to form the recesses. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 214 and the ESL 212 based on a pattern.

A deposition tool 102 and/or a plating tool 112 may be used to deposit the interconnects 238a, 238b, and 240 in the recesses using a CVD technique, a PVD technique, an ALD technique, an electroplating technique, another deposition technique described above in connection with FIG. 1, and/or another suitable deposition technique. In some implementations, a planarization tool 110 is used to planarize the interconnects 238a, 238b, and/or 240 after the interconnects 238a, 238b, and/or 240 are deposited.

As indicated above, FIGS. 5A-5Q are provided as an example. Other examples may differ from what is described with regard to FIGS. 5A-5Q.

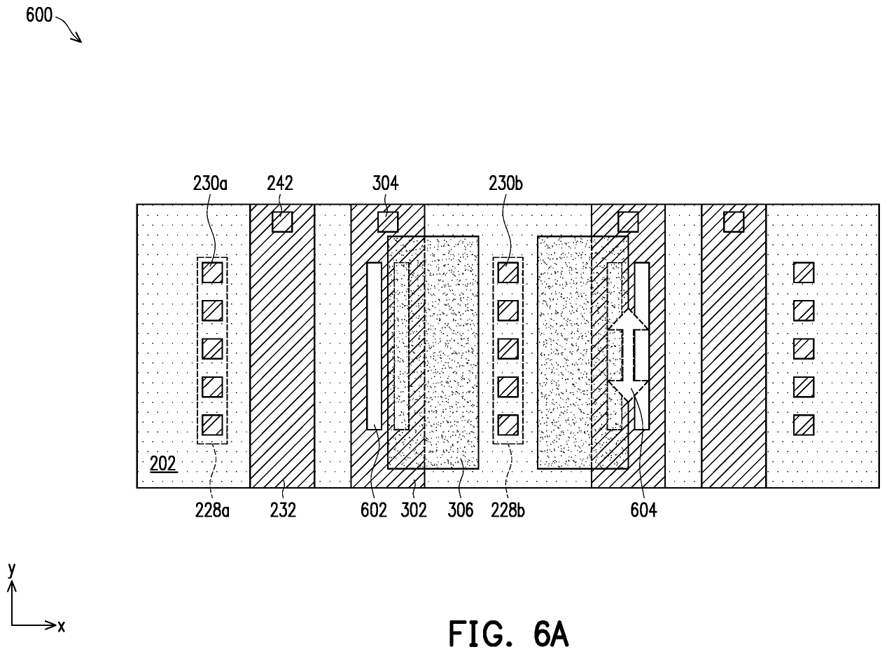

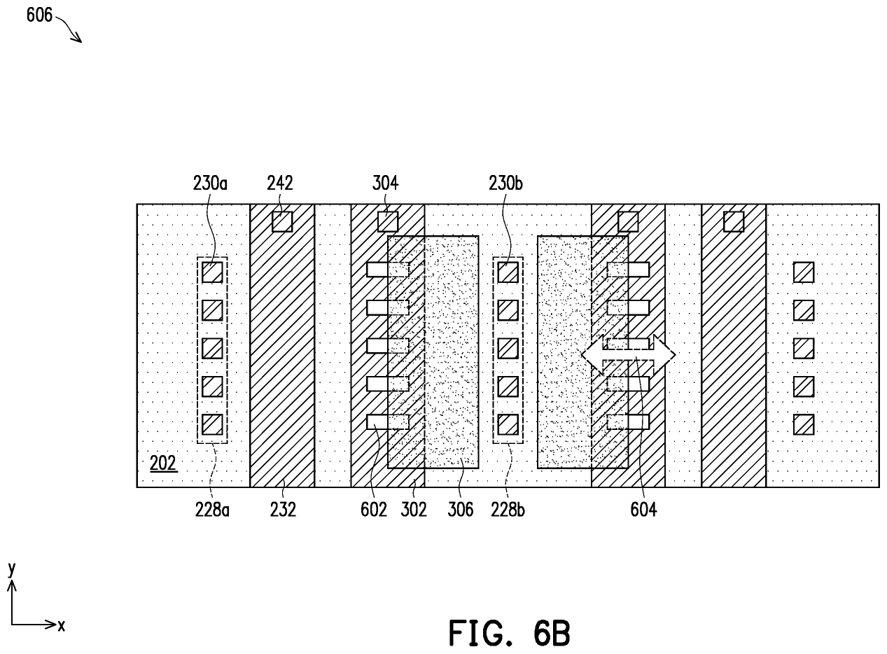

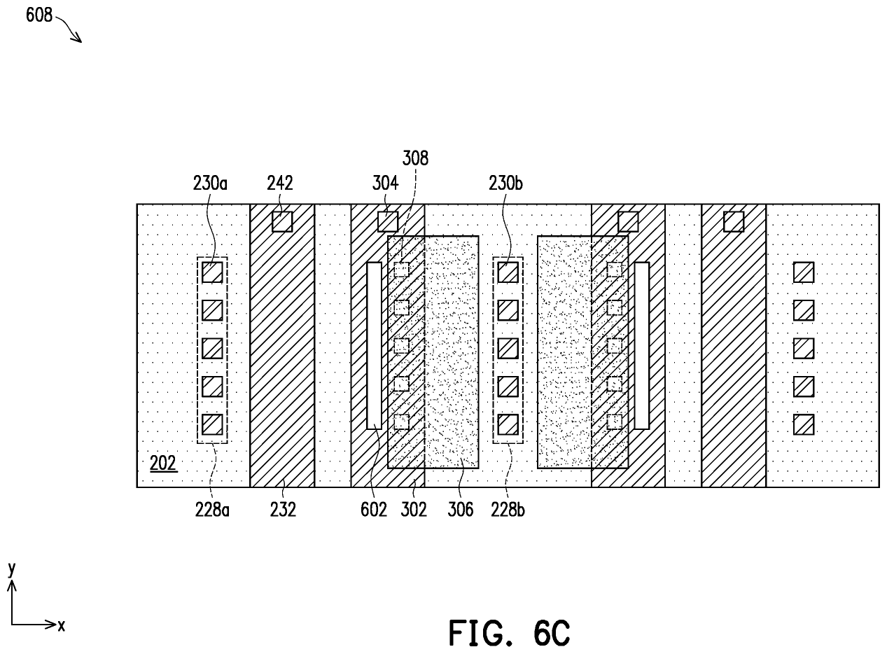

FIGS. 6A-6C are diagrams of example implementations of a transistor structure 300 described herein. FIG. 6A is a diagram of an example implementation 600 of a transistor structure 300 in which dielectric structure(s) 602 are included in and through the field plate structure 302 of the transistor structure 300 instead of the dielectric structure(s) 308. The dielectric structure(s) 602 include elongated dielectric trenches that extend through the field plate structure 302 between the top surface and the bottom surface of the field plate structure 302. The dielectric structure(s) 602 may extend approximately parallel with the field plate structure 302 in the y-direction, and may be arranged in the x-direction.

FIG. 6B illustrates an example implementation 606 in which the dielectric structure(s) 602 may extend approximately perpendicular with the field plate structure 302 in the x-direction, and may be arranged in the y-direction.

The dielectric structure(s) 602 may be formed using a less complex photomask than the dielectric structure(s) 308 while still providing a RESURF effect 604 in the y-direction (in the example implementation 600) or in the x-direction (in the example implementation 606). However, the dielectric structure(s) 308 are capable of providing the RESURF effect 310 in the x-direction and the y-direction.

FIG. 6C is a diagram of an example implementation 608 of a transistor structure 300 in which the field plate structure 302 includes a combination of one or more dielectric structure(s) 308 and one or more dielectric structure(s) 602.

As indicated above, FIGS. 6A-6C are provided as examples. Other examples may differ from what is described with regard to FIGS. 6A-6C.

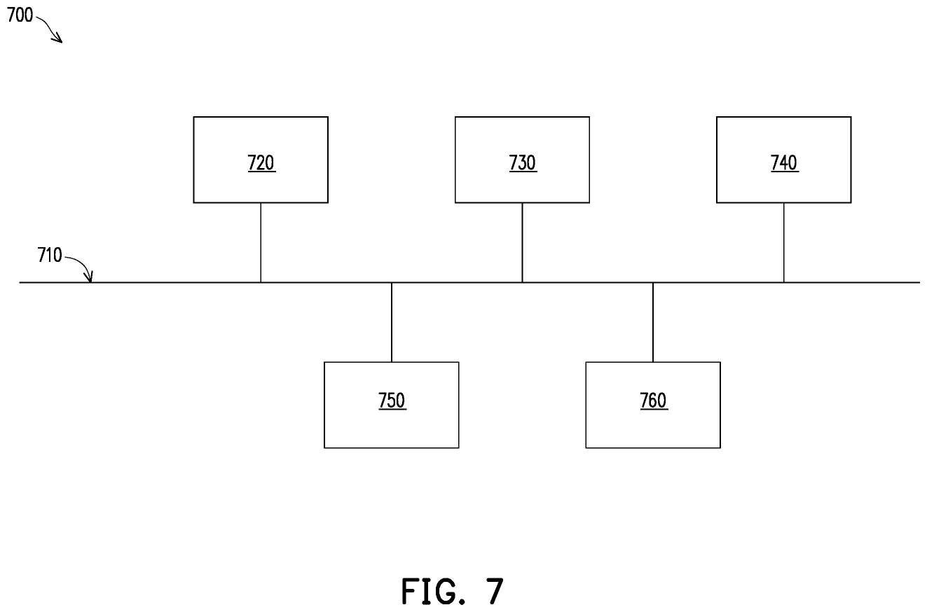

FIG. 7 is a diagram of example components of a device 700 described herein. In some implementations, one or more of the semiconductor processing tools 102-114 and/or the wafer/die transport tool 116 may include one or more devices 700 and/or one or more components of the device 700. As shown in FIG. 7, the device 700 may include a bus 710, a processor 720, a memory 730, an input component 740, an output component 750, and/or a communication component 760.

The bus 710 may include one or more components that enable wired and/or wireless communication among the components of the device 700. The bus 710 may couple together two or more components of FIG. 7, such as via operative coupling, communicative coupling, electronic coupling, and/or electric coupling. For example, the bus 710 may include an electrical connection (e.g., a wire, a trace, and/or a lead) and/or a wireless bus. The processor 720 may include a central processing unit, a graphics processing unit, a microprocessor, a controller, a microcontroller, a digital signal processor, a field-programmable gate array, an application-specific integrated circuit, and/or another type of processing component. The processor 720 may be implemented in hardware, firmware, or a combination of hardware and software. In some implementations, the processor 720 may include one or more processors capable of being programmed to perform one or more operations or processes described elsewhere herein.

The memory 730 may include volatile and/or nonvolatile memory. For example, the memory 730 may include random access memory (RAM), read only memory (ROM), a hard disk drive, and/or another type of memory (e.g., a flash memory, a magnetic memory, and/or an optical memory). The memory 730 may include internal memory (e.g., RAM, ROM, or a hard disk drive) and/or removable memory (e.g., removable via a universal serial bus connection). The memory 730 may be a non-transitory computer-readable medium. The memory 730 may store information, one or more instructions, and/or software (e.g., one or more software applications) related to the operation of the device 700. In some implementations, the memory 730 may include one or more memories that are coupled (e.g., communicatively coupled) to one or more processors (e.g., processor 720), such as via the bus 710. Communicative coupling between a processor 720 and a memory 730 may enable the processor 720 to read and/or process information stored in the memory 730 and/or to store information in the memory 730.

The input component 740 may enable the device 700 to receive input, such as user input and/or sensed input. For example, the input component 740 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 750 may enable the device 700 to provide output, such as via a display, a speaker, and/or a light-emitting diode. The communication component 760 may enable the device 700 to communicate with other devices via a wired connection and/or a wireless connection. For example, the communication component 760 may include a receiver, a transmitter, a transceiver, a modem, a network interface card, and/or an antenna.

The device 700 may perform one or more operations or processes described herein. For example, a non-transitory computer-readable medium (e.g., memory 730) may store a set of instructions (e.g., one or more instructions or code) for execution by the processor 720. The processor 720 may execute the set of instructions to perform one or more operations or processes described herein. In some implementations, execution of the set of instructions, by one or more processors 720, causes the one or more processors 720 and/or the device 700 to perform one or more operations or processes described herein. In some implementations, hardwired circuitry may be used instead of or in combination with the instructions to perform one or more operations or processes described herein. Additionally, or alternatively, the processor 720 may be configured to perform one or more operations or processes described herein. Thus, implementations described herein are not limited to any specific combination of hardware circuitry and software.

The number and arrangement of components shown in FIG. 7 are provided as an example. The device 700 may include additional components, fewer components, different components, or differently arranged components than those shown in FIG. 7. Additionally, or alternatively, a set of components (e.g., one or more components) of the device 700 may perform one or more functions described as being performed by another set of components of the device 700.

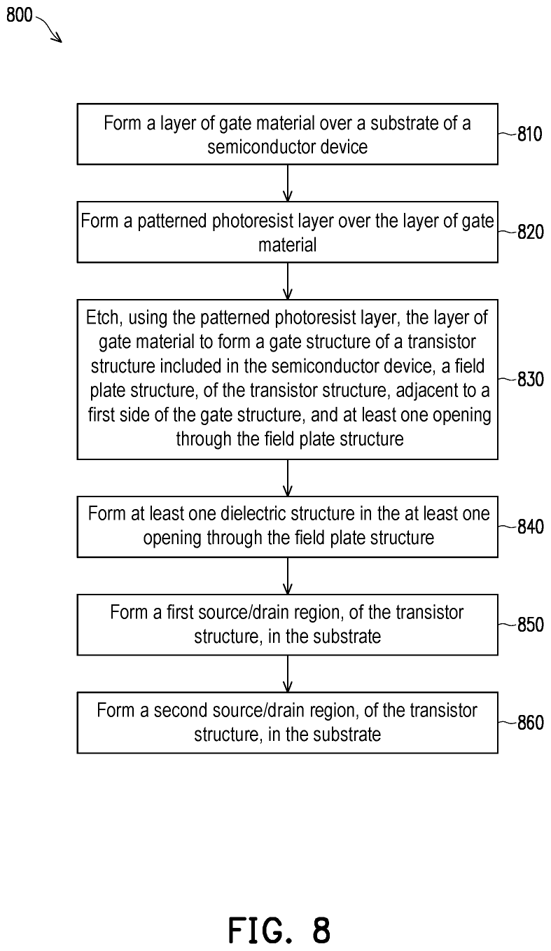

FIG. 8 is a flowchart of an example process 800 associated with forming a semiconductor device described herein. In some implementations, one or more process blocks of FIG. 8 are performed using one or more semiconductor processing tools (e.g., one or more of the semiconductor processing tools 102-114). Additionally, or alternatively, one or more process blocks of FIG. 8 may be performed using one or more components of device 700, such as processor 720, memory 730, input component 740, output component 750, and/or communication component 760.

As shown in FIG. 8, process 800 may include forming a layer of gate material over a substrate of a semiconductor device (block 810). For example, one or more of the semiconductor processing tools 102-114 may be used to form a layer 504 of gate material over a substrate 202 of a semiconductor device 200, as described herein.

As further shown in FIG. 8, process 800 may include forming a patterned photoresist layer over the layer of gate material (block 820). For example, one or more of the semiconductor processing tools 102-114 may be used to form a patterned photoresist layer 506 over the layer 504 of gate material, as described herein.

As further shown in FIG. 8, process 800 may include etching, using the patterned photoresist layer, the layer of gate material to form a gate structure of a transistor structure included in the semiconductor device, a field plate structure, of the transistor structure, adjacent to a first side of the gate structure, and at least one opening through the field plate structure (block 830). For example, one or more of the semiconductor processing tools 102-114 may be used to etch, using the patterned photoresist layer 506, the layer 504 of gate material to form a gate structure 232 of a transistor structure 300 included in the semiconductor device 200, a field plate structure 302, of the transistor structure 300, adjacent to a first side of the gate structure 232, and at least one opening 512 through the field plate structure 302, as described herein.

As further shown in FIG. 8, process 800 may include forming at least one dielectric structure in the at least one opening through the field plate structure (block 840). For example, one or more of the semiconductor processing tools 102-114 may be used to form at least one dielectric structure (e.g., dielectric structures 308, dielectric structures 602) in the at least one opening 512 through the field plate structure 302, as described herein.

As further shown in FIG. 8, process 800 may include forming a first source/drain region, of the transistor structure, in the substrate (block 850). For example, one or more of the semiconductor processing tools 102-114 may be used to form a first source/drain region 228a, of the transistor structure 300, in the substrate 202, as described herein. In some implementations, the first source/drain region 228a is adjacent to a second side of the gate structure 232 opposing the first side.

As further shown in FIG. 8, process 800 may include forming a second source/drain region, of the transistor structure, in the substrate (block 860). For example, one or more of the semiconductor processing tools 102-114 may be used to form a second source/drain region 228b, of the transistor structure 300, in the substrate 202, as described herein. In some implementations, the second source/drain region 228b is adjacent to the field plate structure 302.

Process 800 may include additional implementations, such as any single implementation or any combination of implementations described below and/or in connection with one or more other processes described elsewhere herein.

In a first implementation, process 800 includes forming a plurality of offset spacers 516 in the plurality of openings 512, where forming the at least one dielectric structure includes forming a plurality of dielectric structures after forming the plurality of offset spacers 516.

In a second implementation, alone or in combination with the first implementation, the plurality of dielectric structures have concave top surfaces.

In a third implementation, alone or in combination with one or more of the first and second implementations, process 800 includes forming, between the gate structure 232 and the field plate structure 302, a merged sidewall spacer (e.g., the inner sidewall spacer 326).

In a fourth implementation, alone or in combination with one or more of the first through third implementations, the merged sidewall spacer has a concave top surface.

In a fifth implementation, alone or in combination with one or more of the first through fourth implementations, process 800 includes forming an RPO layer 306 on the gate structure 232 and on the field plate structure 302, and removing a portion of the RPO layer 306 from the gate structure 232 such that a remaining portion of the RPO layer 306 remains on the field plate structure 302.

In a sixth implementation, alone or in combination with one or more of the first through fifth implementations, process 800 includes removing another portion of the RPO layer 306 from the field plate structure 302 such that the remaining portion of the RPO layer 306 remains on less than an entirety of the field plate structure 302.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

In this way, a transistor structure (e.g., a high-voltage transistor) includes a field plate structure and at least one dielectric structure through the field plate structure. The dielectric structures may be arranged in a grid in a top view of the transistor structure. The dielectric structure(s) enable the field plate structure to be positioned closer to a gate structure of the transistor than without the dielectric structure(s), which enables the length of the field plate structure to be increased without increasing the overall length (or with minimal length increase) of the transistor.

As described in greater detail above, some implementations described herein provide a semiconductor device. The semiconductor device includes a first source/drain region in a substrate. The semiconductor device includes a second source/drain region in the substrate. The semiconductor device includes a gate structure over the substrate and between the first source/drain region and the second source/drain region. The semiconductor device includes a field plate structure over the substrate and between the gate structure and the second source/drain region. The semiconductor device includes at least one dielectric structure through the field plate structure.

As described in greater detail above, some implementations described herein provide a method. The method includes forming a layer of gate material over a substrate of a semiconductor device. The method includes forming a patterned photoresist layer over the layer of gate material. The method includes etching, using the patterned photoresist layer, the layer of gate material to form a gate structure of a transistor structure included in the semiconductor device, a field plate structure, of the transistor structure, adjacent to a first side of the gate structure, and at least one opening through the field plate structure. The method includes forming at least one dielectric structure in the at least one opening through the field plate structure. The method includes forming a first source/drain region, of the transistor structure, in the substrate, where the first source/drain region is adjacent to a second side of the gate structure opposing the first side. The method includes forming a second source/drain region, of the transistor structure, in the substrate, where the second source/drain region is adjacent to the field plate structure.

As described in greater detail above, some implementations described herein provide a semiconductor device. The semiconductor device includes a first source/drain region in a substrate. The semiconductor device includes a second source/drain region in the substrate. The semiconductor device includes a gate structure over the substrate and between the first source/drain region and the second source/drain region. The semiconductor device includes a field plate structure over the substrate and between the gate structure and the second source/drain region. The semiconductor device includes a plurality of dielectric structures through the field plate structure. The semiconductor device includes an RPO layer on less than an entirety of a length of the field plate structure.

As described in greater detail above, some implementations described herein provide a semiconductor device. The semiconductor device includes a source/drain region in a substrate. The semiconductor device includes a gate structure over the substrate and adjacent to the source/drain region. The semiconductor device includes a field plate structure over the substrate and between the gate structure and the source/drain region. The semiconductor device includes a first dielectric structure through the field plate structure. The semiconductor device includes a second dielectric structure, adjacent to the first dielectric structure, through the field plate structure. The semiconductor device includes an RPO layer on less than an entirety of a length of the field plate structure. The RPO layer is included over the second dielectric structure and not the first dielectric structure.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first source/drain region in a substrate;
a second source/drain region in the substrate;
a gate structure over the substrate and between the first source/drain region and the second source/drain region;
a field plate structure over the substrate and between the gate structure and the second source/drain region; and
a at least one dielectric structure through the field plate structure.

2. The semiconductor device of claim 1, wherein the at least one dielectric structure comprises a plurality of dielectric plugs.

3. The semiconductor device of claim 2, wherein the plurality of dielectric plugs are arranged in a plurality of rows in a first direction in a top view of the semiconductor device; and
wherein the plurality of dielectric plugs are arranged in a plurality of columns in a second direction in a top view of the semiconductor device opposing the first direction.

4. The semiconductor device of claim 1, wherein the at least one dielectric structure comprises a plurality of dielectric trenches.

5. The semiconductor device of claim 1, further comprising:
a first outer sidewall spacer on a first sidewall of the gate structure;
a second outer sidewall spacer on a first sidewall of the field plate structure; and
an inner sidewall spacer on a second sidewall of the gate structure and on a second sidewall of the field plate structure.

6. The semiconductor device of claim 5, wherein the inner sidewall spacer extends between the second sidewall of the gate structure and the second sidewall of the field plate structure.

7. The semiconductor device of claim 1, wherein the at least one dielectric structure continuously extends between a top surface of the field plate structure and a bottom surface of the field plate structure.

8. A method, comprising:
forming a layer of gate material over a substrate of a semiconductor device;
forming a patterned photoresist layer over the layer of gate material;
etching, using the patterned photoresist layer, the layer of gate material to form:
a gate structure of a transistor structure included in the semiconductor device,
a field plate structure, of the transistor structure, adjacent to a first side of the gate structure, and
at least one opening through the field plate structure;
forming at least one dielectric structure in the at least one opening through the field plate structure;
forming a first source/drain region, of the transistor structure, in the substrate,
wherein the first source/drain region is adjacent to a second side of the gate structure opposing the first side; and
forming a second source/drain region, of the transistor structure, in the substrate,
wherein the second source/drain region is adjacent to the field plate structure.

9. The method of claim 8, further comprising:
forming at least one offset spacer in the at least one opening,
wherein forming the at least one dielectric structure comprises:
forming the at least one dielectric structure after forming the at least one offset spacer.

10. The method of claim 8, wherein the at least one dielectric structure has a concave top surface.

11. The method of claim 8, further comprising:
forming, between the gate structure and the field plate structure, a merged sidewall spacer.

12. The method of claim 11, wherein the merged sidewall spacer has a concave top surface.

13. The method of claim 8, further comprising:
forming a resist protective oxide (RPO) layer on the gate structure and on the field plate structure; and
removing a portion of the RPO layer from the gate structure such that a remaining portion of the RPO layer remains on the field plate structure.

14. The method of claim 13, further comprising:
removing another portion of the RPO layer from the field plate structure such that the remaining portion of the RPO layer remains on less than an entirety of the field plate structure.

15. A semiconductor device, comprising:
a source/drain region in a substrate;
a gate structure over the substrate and adjacent to the source/drain region;
a field plate structure over the substrate and between the gate structure and the source/drain region;
a first dielectric structure through the field plate structure;
a second dielectric structure, adjacent to the first dielectric structure, through the field plate structure; and
a resist protective oxide (RPO) layer on less than an entirety of a length of the field plate structure,
wherein the RPO layer is included over the second dielectric structure and not the first dielectric structure.

16. The semiconductor device of claim 15, further comprising:
a third dielectric structure through the field plate structure,
wherein the third dielectric structure is adjacent to the first dielectric structure, and
wherein the second dielectric structure extends alongside the first dielectric structure and the third dielectric structure.

17. The semiconductor device of claim 15, wherein a first end of the RPO layer is located adjacent to the source/drain region; and
wherein a second end of the RPO layer, opposing the first end, is located on the field plate structure.

18. The semiconductor device of claim 15, wherein the second end of the RPO layer is located between the first dielectric structure and the second dielectric structure.

19. The semiconductor device of claim 15, wherein the first dielectric structure comprises a dielectric plug.

20. The semiconductor device of claim 19, wherein the second dielectric structure comprises a dielectric trench.
